(19) United States
(12) Patent Application Publication
(10) Pub. No.: US 2023/0154889 A1
(43) Pub. Date: May 18, 2023

(54) SEMICONDUCTOR DEVICE MANUFACTURING METHOD AND JIG SET

(71) Applicant: FUJI ELECTRIC CO., LTD., Kawasaki-shi (JP)

(72) Inventor: Manabu ISHIKAWA, Matsumoto-city, Nagano (JP)

(73) Assignee: FUJI ELECTRIC CO., LTD., Kawasaki-shi (JP)

(21) Appl. No.: 17/954,215

(22) Filed: Sep. 27, 2022

(30) Foreign Application Priority Data
Nov. 17, 2021 (JP) 2021-186925

(51) Int. Cl. H01L 23/00; H01L 25/07; H01L 21/48; H01L 23/373

(52) U.S. Cl. CPC H01L 24/84; H01L 24/37; H01L 24/40; H01L 24/77; H01L 25/072; H01L 21/4882; H01L 23/3735; H01L 2224/37147; H01L 2224/37124; H01L 2224/84201; H01L 2224/77754; H01L 2224/7755; H01L 2224/40499; H01L 2224/29111; H01L 2224/29113; H01L 2224/29118; H01L 2224/29109; H01L 2224/29139; H01L 2224/29147; H01L 2924/0132; H01L 2924/0133; H01L 2224/40225; H01L 2224/32225; H01L 2224/73263; H01L 2224/92246; H01L 24/29; H01L 24/32; H01L 24/73; H01L 24/92; H01L 24/48; H01L 2224/48225; H01L 2224/73221

(57) ABSTRACT

A semiconductor device manufacturing method, includes: a preparing process for preparing a conductive plate, a semiconductor chip arranged over the conductive plate with a first bonding material therebetween, and a connection terminal including a bonding portion arranged over the semiconductor chip with a second bonding material therebetween; a first jig arrangement process for arranging a first guide jig, through which a first guide hole pierces, over the conductive plate, such that the first guide hole corresponds to the bonding portion in a plan view of the semiconductor device; and a first pressing process for inserting a pillar-shaped pressing jig, which includes a pressing portion at a lower end portion thereof, into the first guide hole, and pressing the bonding portion of the connection terminal to a side of the conductive plate with the pressing portion.

### CROSS-REFERENCE TO RELATED APPLICATION

This application is based upon and claims the benefit of priority of the prior Japanese Patent Application No. 2021-186925, filed on Nov. 17, 2021, the entire contents of which are incorporated herein by reference.

### BACKGROUND OF THE INVENTION

### 1. Field of the Invention

The embodiments discussed herein relate to a semiconductor device manufacturing method and a jig set.

### 2. Background of the Related Art

Semiconductor devices include power devices used as a power converter. The power devices include semiconductor chips such as insulated gate bipolar transistors (IGBTs) or power metal oxide semiconductor field effect transistors (MOSFETs). Such semiconductor devices include at least semiconductor modules and radiation plates to which the semiconductor modules are bonded. The semiconductor modules may include semiconductor chips, an insulated circuit board to which the semiconductor chips are bonded, and lead frames bonded to the semiconductor chips. When such a semiconductor device is manufactured, a positioning jig is used for bonding a semiconductor module to a determined area of a radiation plate. Furthermore, a weight is placed on the positioning jig.

Examples in which a jig is used for manufacturing are as follows. For example, a base steel is positioned and located in a concave portion of a tray and a first jig in which a first bored hole portion is formed is located in the concave portion over the base steel. Solder and a board are laminated in order and located over the base steel positioned in the first bored hole portion. Furthermore, a second jig in which a second bored hole portion is formed is fitted in the first bored hole portion, solder and a chip are laminated in order over the board positioned in the second bored hole portion, and a weight is fitted in the second bored hole portion (see, for example, Japanese Laid-open Patent Publication No. 2012-238638).

Furthermore, both end portions of a lead terminal protruding from a metal block are set on a foundation of a jig and are fixed by lower portions of a pair of sandwiching members of the jig on side portions of the metal block. As a result, the lead terminal is fixed at a predetermined level (see, for example, Japanese Laid-open Patent Publication No. 2014-187245).

By the way, when a semiconductor module is bonded to a radiation plate with solder, the solder is melted by heating. At this time, a thermal expansion coefficient differs among an insulated circuit board, a semiconductor chip, and a lead frame. As a result, the semiconductor chip may warp. If the lead frame is bonded in a state in which the semiconductor chip is warped, then the thickness of solder with which the semiconductor chip and the lead frame are bonded becomes uneven. As a result, even if the semiconductor chip and the lead frame are electrically connected, an electrical malfunction may occur in the semiconductor chip. This leads to deterioration in the reliability of a semiconductor device.

### SUMMARY OF THE INVENTION

According to an aspect, there is provided a semiconductor device manufacturing method including a preparing process for preparing a conductive plate, a semiconductor chip arranged over the conductive plate with a first bonding material therebetween, and a connection terminal including a bonding portion arranged over the semiconductor chip with a second bonding material therebetween; a first jig arrangement process for arranging a first guide jig, through which a first guide hole pierces, over the conductive plate, such that the first guide hole corresponds to the bonding portion in a plan view of the semiconductor device; and a first pressing process for inserting a pillar-shaped pressing jig, which includes a pressing portion at a lower end portion thereof, into the first guide hole, and pressing the bonding portion of the connection terminal to a side of the conductive plate with the pressing portion.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a side view of a semiconductor device according to a first embodiment;

FIG. 2 is a flow chart of a method for manufacturing the semiconductor device according to the first embodiment;

FIG. 3 is a flow chart of a semiconductor unit manufacturing process included in the method for manufacturing the semiconductor device according to the first embodiment;

FIG. 4 is a sectional view illustrative of an insulated circuit board setting subprocess included in the semiconductor unit manufacturing process included in the method for manufacturing the semiconductor device according to the first embodiment;

FIG. 5 is a plan view illustrative of the insulated circuit board setting subprocess included in the semiconductor unit manufacturing process included in the method for manufacturing the semiconductor device according to the first embodiment;

FIG. 6 is a sectional view illustrative of a semiconductor chip setting subprocess included in the semiconductor unit manufacturing process included in the method for manufacturing the semiconductor device according to the first embodiment;

FIG. 7 is a plan view illustrative of the semiconductor chip setting subprocess included in the semiconductor unit manufacturing process included in the method for manufacturing the semiconductor device according to the first embodiment;

FIG. 8 is a sectional view illustrative of a lead frame setting subprocess included in the semiconductor unit manufacturing process included in the method for manufacturing the semiconductor device according to the first embodiment;

FIG. 9 is a plan view illustrative of the lead frame setting subprocess included in the semiconductor unit manufacturing process included in the method for manufacturing the semiconductor device according to the first embodiment;

FIG. 10 is a sectional view illustrative of a pressing jig setting subprocess included in the semiconductor unit manufacturing process included in the method for manufacturing the semiconductor device according to the first embodiment;

FIG. 11 is a sectional view illustrative of a semiconductor unit manufacturing process included in a method for manufacturing a semiconductor device taken as a reference example;

FIG. 12 is a flow chart of a bonding process included in the method for manufacturing the semiconductor device according to the first embodiment;

FIG. 13 is a sectional view illustrative of a radiation plate setting subprocess included in the bonding process included in the method for manufacturing the semiconductor device according to the first embodiment;

FIG. 14 is a plan view illustrative of the radiation plate setting subprocess included in the bonding process included in the method for manufacturing the semiconductor device according to the first embodiment;

FIG. 15 is a sectional view illustrative of a radiation plate fixing subprocess included in the bonding process included in the method for manufacturing the semiconductor device according to the first embodiment;

FIG. 16 is a plan view illustrative of the radiation plate fixing subprocess included in the bonding process included in the method for manufacturing the semiconductor device according to the first embodiment;

FIG. 17 is a sectional view illustrative of a semiconductor unit positioning subprocess included in the bonding process included in the method for manufacturing the semiconductor device according to the first embodiment (part 1);

FIG. 18 is a plan view illustrative of the semiconductor unit positioning subprocess included in the bonding process included in the method for manufacturing the semiconductor device according to the first embodiment (part 1);

FIG. 19 is a sectional view illustrative of a semiconductor unit positioning subprocess included in the bonding process included in the method for manufacturing the semiconductor device according to the first embodiment (part 2);

FIG. 20 is a plan view illustrative of the semiconductor unit positioning subprocess included in the bonding process included in the method for manufacturing the semiconductor device according to the first embodiment (part 2);

FIG. 21 is a sectional view illustrative of a spacer jig setting subprocess included in the bonding process included in the method for manufacturing the semiconductor device according to the first embodiment;

FIG. 22 is a plan view illustrative of the spacer jig setting subprocess included in the bonding process included in the method for manufacturing the semiconductor device according to the first embodiment;

FIG. 23 is a sectional view illustrative of a weight setting subprocess included in the bonding process included in the method for manufacturing the semiconductor device according to the first embodiment;

FIG. 24 is a plan view illustrative of the weight setting subprocess included in the bonding process included in the method for manufacturing the semiconductor device according to the first embodiment;

FIG. 25 is a sectional view illustrative of a pressing jig setting subprocess included in the bonding process included in the method for manufacturing the semiconductor device according to the first embodiment;

FIG. 26 is a plan view illustrative of the pressing jig setting subprocess included in the bonding process included in the method for manufacturing the semiconductor device according to the first embodiment;

FIG. 27 is a sectional view illustrative of a weight setting subprocess included in a bonding process included in a method for manufacturing a semiconductor device according to a second embodiment;

FIG. 28 is a sectional view illustrative of a pressing jig setting subprocess included in the bonding process included in the method for manufacturing the semiconductor device according to the second embodiment;

FIG. 29 is a plan view illustrative of the pressing jig setting subprocess included in the bonding process included in the method for manufacturing the semiconductor device according to the second embodiment;

FIG. 30 is a plan view illustrative of a semiconductor device according to a third embodiment;

FIG. 31 is a perspective view of a semiconductor unit included in the semiconductor device according to the third embodiment;

FIG. 32 is a sectional view illustrative of a weight setting subprocess included in a bonding process included in a method for manufacturing the semiconductor device according to the third embodiment;

FIG. 33 is a plan view illustrative of the weight setting subprocess included in the bonding process included in the method for manufacturing the semiconductor device according to the third embodiment; and

FIG. 34 is a sectional view illustrative of a pressing jig setting subprocess included in the bonding process included in the method for manufacturing the semiconductor device according to the third embodiment.

### DETAILED DESCRIPTION OF THE INVENTION

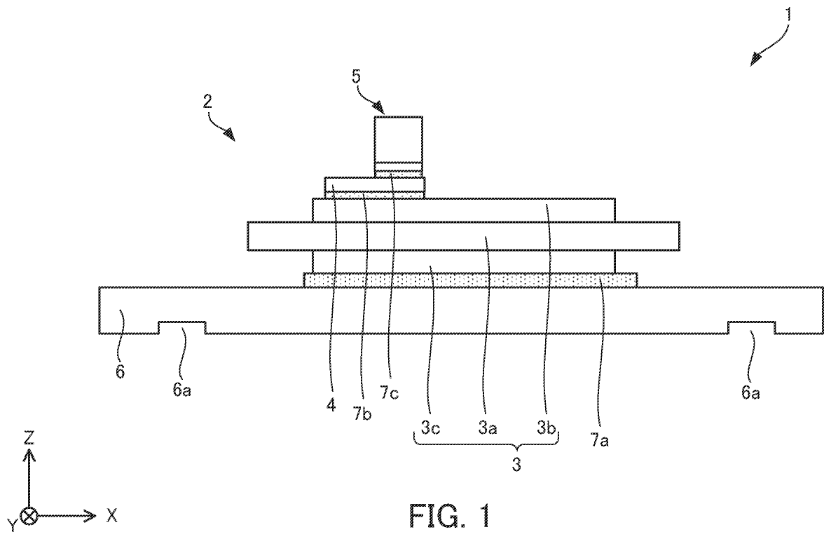

Embodiments will now be described by reference to the accompanying drawings. In the following description, a “front surface” or an “upper surface” indicates an X-Y plane of a semiconductor device 1 of FIG. 1 which faces the upper side (+Z direction). Similarly, an “upside” indicates the upward direction (+Z direction) of the semiconductor device 1 of FIG. 1. A “back surface” or a “lower surface” indicates the X-Y plane of the semiconductor device 1 of FIG. 1 which faces the lower side (−Z direction). Similarly, a “downside” indicates the downward direction (−Z direction) of the semiconductor device 1 of FIG. 1. These terms mean the same directions at need in the other drawings. A “high position” indicates a position on the upper side (+Z side) of the semiconductor device 1 of FIG. 1. Similarly, a “low position” indicates a position on the lower side (−Z side) of the semiconductor device 1 of FIG. 1. The “front surface,” the “upper surface,” the “upside,” the “back surface,” the “lower surface,” the “downside,” and a “side” are simply used as expedient representation for specifying relative positional relationships and do not limit the technical idea of the present disclosure. For example, the “upside” or the “downside” does not always mean the vertical direction relative to the ground. That is to say, a direction indicated by the “upside” or the “downside” is not limited to the gravity direction. Furthermore, in the following description a “main ingredient” indicates an ingredient contained at a rate of 80 volume percent (vol %) or more.

Furthermore, in the drawings used for describing the following embodiments, a component which appears first is marked with a numeral and the numeral of the component may be omitted in later drawings. If the numeral of the component is omitted in the later drawings, then the drawing in which it appears first is referred to.

### First Embodiment

A semiconductor device 1 according to a first embodiment will be described with reference to FIG. 1. FIG. 1 is a side view of a semiconductor device according to a first embodiment. A semiconductor device 1 includes at least a radiation plate 6 and a semiconductor unit 2. With the semiconductor device 1, a case which surrounds the semiconductor unit 2 may be located over the radiation plate 6. In this case, the semiconductor unit 2 in the case is sealed with a sealing member and a lead frame 5 vertically extends upward. Alternatively, with the semiconductor device 1, it may be that the back surface of the radiation plate 6 is exposed, the semiconductor unit 2 over the radiation plate 6 is sealed with a sealing member, and the lead frame 5 vertically extends upward. FIG. 1 illustrates the minimum structure of the semiconductor device 1.

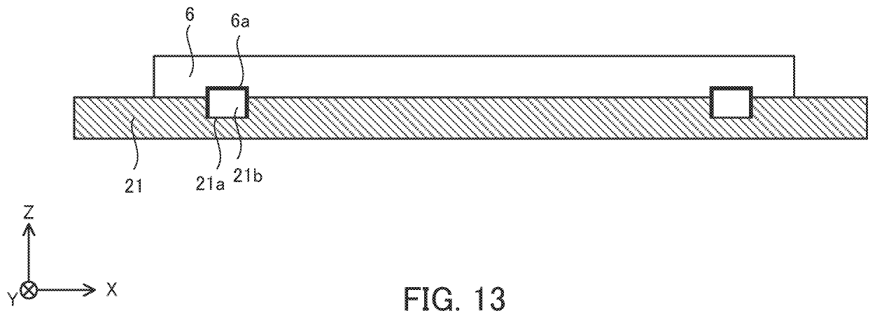

The radiation plate 6 is rectangular in plan view. Each corner portion of the radiation plate 6 may be R-chamfered or C-chamfered. A fixing groove 6a may be cut in the back surface of the radiation plate 6. The fixing groove 6a will be described later (FIG. 13). The radiation plate 6 is made of metal, such as aluminum, iron, silver, copper, or an alloy containing at least one of them, having high thermal conductivity. In order to improve corrosion resistance, plating treatment may be performed on the surface of the radiation plate 6. At this time, nickel, a nickel-phosphorus alloy, a nickel-boron alloy, or the like is used as a plating material. The semiconductor unit 2 is arranged over a central portion of the front surface of the radiation plate 6 with a bonding member 7a therebetween. In this embodiment, a case where one semiconductor unit 2 is arranged over the radiation plate 6 is taken as an example. However, a plurality of semiconductor units 2 may be arranged. In that case, the semiconductor units 2 may be arranged in line or may be arranged in n rows and m columns according to the number of the semiconductor units 2.

Furthermore, with the semiconductor unit 2, an insulated circuit board 3, a semiconductor chip 4, and a lead frame 5 are laminated in order with bonding members 7b and 7c, respectively, therebetween. The composition of the bonding members 7b and 7c is the same as that of the bonding member 7a.

The insulated circuit board 3 is rectangular in plan view. The insulated circuit board 3 includes an insulating plate 3a, a circuit pattern 3b formed over the front surface of the insulating plate 3a, and a metal plate 3c formed on the back surface of the insulating plate 3a. The external shape of the circuit pattern 3b and the metal plate 3c is smaller in plan view than that of the insulating plate 3a. The circuit pattern 3b and the metal plate 3c are formed inside the insulating plate 3a. The shape or the number of the circuit pattern 3b is an example.

The insulating plate 3a is rectangular in plan view. Furthermore, each corner portion of the insulating plate 3a may be C-chamfered or R-chamfered. The insulating plate 3a is made of a ceramic having high thermal conductivity. Such a ceramic is made of a material which contains as a main ingredient aluminum oxide, aluminum nitride, silicon nitride, or the like. In addition, the thickness of the insulating plate 3a is greater than or equal to 0.2 mm and smaller than or equal to 2.0 mm.

The circuit pattern 3b is formed over the entire surface except an edge portion of the insulating plate 3a. An end portion of the circuit pattern 3b which faces the outer periphery of the insulating plate 3a is preferably superimposed in plan view over an end portion of the metal plate 3c on the side of the outer periphery of the insulating plate 3a. Accordingly, with the insulated circuit board 3, stress balance is maintained between the circuit pattern 3b and the metal plate 3c formed on the back surface of the insulating plate 3a. This suppresses an excessive warp of the insulating plate 3a or damage, such as a crack, to the insulating plate 3a. Furthermore, the thickness of the circuit pattern 3b is greater than or equal to 0.1 mm and smaller than or equal to 2.0 mm. The circuit pattern 3b is made of metal, such as copper, aluminum, or an alloy containing at least one of them, having good electrical conductivity. In addition, in order to improve corrosion resistance, plating treatment may be performed on the surface of the circuit pattern 3b. At this time, nickel, a nickel-phosphorus alloy, a nickel-boron alloy or the like is used as a plating material. The circuit pattern 3b is formed over the insulating plate 3a in the following way. A metal layer is formed over the front surface of the insulating plate 3a and treatment, such as etching, is performed on the metal layer. By doing so, the circuit pattern 3b is obtained. Alternatively, the circuit pattern 3b cut in advance out of a metal plate may be pressure-bonded to the front surface of the insulating plate 3a. The circuit pattern 3b is taken as an example. The number, shape, size, or the like of circuit patterns may be properly selected at need.

The metal plate 3c is rectangular in plan view. Furthermore, for example, each corner portion of the metal plate 3c may be C-chamfered or R-chamfered. The metal plate 3c is smaller in size than the insulating plate 3a and is formed on the entire back surface except an edge portion of the insulating plate 3a. The metal plate 3c contains as a main ingredient metal having high thermal conductivity. Such metal is copper, aluminum, an alloy containing at least one of them, or the like. In addition, the thickness of the metal plate 3c is greater than or equal to 0.1 mm and smaller than or equal to 2.0 mm. In order to improve the corrosion resistance of the metal plate 3c, plating treatment may be performed. At this time, nickel, a nickel-phosphorus alloy, a nickel-boron alloy, or the like is used as a plating material.

A direct copper bonding (DCB) substrate, an active metal brazed (AMB) substrate, or the like may be used as the insulated circuit board 3 having the above structure. The insulated circuit board 3 conducts heat generated by the semiconductor chip 4 described later via the circuit pattern 3b, the insulating plate 3a, and the metal plate 3c to the back surface of the insulated circuit board 3 in order to dissipate the heat. The insulated circuit board 3 is bonded to the radiation plate 6 with the bonding member 7a.

Pb-free solder is used as the bonding member 7a. The Pb-free solder contains as a main ingredient at least one of a tin-silver-copper alloy, a tin-zinc-bismuth alloy, a tin-copper alloy, and a tin-silver-indium-bismuth alloy, and the like. Moreover, the bonding member 7a may contain an additive such as nickel, germanium, cobalt, or silicon. The bonding member 7a containing an additive improves wettability, a gloss, and bonding strength and reliability is improved.

The semiconductor chip 4 contains as a main ingredient silicon, silicon carbide, or gallium nitride. The semiconductor chip 4 includes a switching element or a diode element. The switching element is an IGBT, a power MOSFET, or the like. If the semiconductor chip 4 is an IGBT, then the semiconductor chip 4 has a collector electrode as a main electrode on the back surface and has a gate electrode and an emitter electrode as a main electrode on the front surface. If the semiconductor chip 4 is a power MOSFET, then the semiconductor chip 4 has a drain electrode as a main electrode on the back surface and has a gate electrode and a source electrode as a main electrode on the front surface. The diode element is a free wheeling diode (FWD) such as a Schottky barrier diode (SBD) or a P-intrinsic-N (PiN) diode. If the semiconductor chip 4 is a diode element, then the semiconductor chip 4 has a cathode electrode as a main electrode on the back surface and has an anode electrode as a main electrode on the front surface.

Furthermore, the semiconductor chip 4 may be a reverse-conducting (RC)-IGBT. With the RC-IGBT, an IGBT, which is a switching element, and an FWD, which is a diode element, are formed in one chip. In this case, for example, the semiconductor chip 4 has a collector electrode (positive-electrode electrode) and an anode electrode as main electrodes on the back surface and has a gate electrode as a control electrode and an emitter electrode (negative-electrode electrode) and a cathode electrode as main electrodes on the front surface.

The back surface of the semiconductor chip 4 is bonded to the circuit pattern 3b with the bonding member 7b. The bonding member 7b is Pb-free solder. This is the same with the bonding member 7a. The composition of the bonding member 7b may be the same as that of the bonding member 7a. Alternatively, a bonding material containing fine metal nanoparticles (fine metal particle sintered body) may be used as the bonding member 7b. Fine metal particles are, for example, a silver particle sintered body. Fine metal particle sintered bodies include a nanoparticle sintered body and a microparticle sintered body. A nanoparticle sintered body is obtained by sintering metal particles having an average particle diameter larger than or equal to about 1 nm and smaller than or equal to about 200 nm and is a porous metal body in a state in which particles are linked and stretch in a row. A microparticle sintered body is obtained by sintering metal particles having an average particle diameter larger than or equal to about 1 nm and smaller than or equal to about 10 μm and is a porous metal body in a state in which particles are linked and stretch in a row. Furthermore, a mixed particle sintered body in which nanoparticles and microparticle are mixed and the like are known. A bonding material before sintering (fine metal sintered body bonding material) is a bonding material in which the surface of each metal particle is covered with organic matter to prevent flocculation, whose dispersibility in a solvent is improved, and which is made into a paste, a bonding material in which metal particles (such as silver oxide) and a reducing solvent having reducing action are made into a paste, or the like. The thickness (before heating and bonding) of the bonding member 7b is greater than or equal to 0.05 mm and smaller than or equal to 0.30 mm. In particular, the thickness of the bonding member 7b is preferably greater than or equal to 0.10 mm and smaller than or equal to 0.20 mm. If the thickness of the bonding member 7b is this range, then bonding strength is satisfied, the amount of scattering is not large, and thermal resistance is suppressed. Furthermore, for example, the thickness of the semiconductor chip 4 is greater than or equal to 180 μm and smaller than or equal to 220 μm and is about 200 μm on average.

For example, the lead frame 5 is a wiring member which electrically connects the semiconductor chip 4 (in particular, the main electrode on the front surface) and the circuit pattern 3b and external terminals and the like. In this embodiment, the lead frame 5 is bonded to the semiconductor chip 4. The lead frame 5 includes a bonding portion 5a and a wiring portion 5b. Each of the bonding portion 5a and the wiring portion 5b has the shape of a flat plate. For example, the bonding portion 5a and the wiring portion 5b are connected so as to form the shape of the letter “L” in side view.

The lead frame 5 is made of a material, such as copper, aluminum, or an alloy containing at least one of them, having good electrical conductivity. The thickness of the lead frame 5 is preferably greater than or equal to 0.20 mm and smaller than or equal to 4.00 mm. The thickness of the lead frame 5 is more preferably greater than or equal to 0.50 mm and smaller than or equal to 1.50 mm. Furthermore, for example, in order to improve corrosion resistance, a plating material may be formed on the surface of the lead frame 5 by plating treatment. The plating material used at this time may be nickel, a nickel alloy, or the like. The shape of the lead frame 5 in this embodiment is an example. In addition, the back surface of the lead frame 5 is also bonded to a determined area of the semiconductor chip 4 with the bonding member 7c. The bonding member 7c is Pb-free solder. This is the same with the bonding member 7a. The composition of the bonding member 7c may be the same as that of the bonding member 7a.

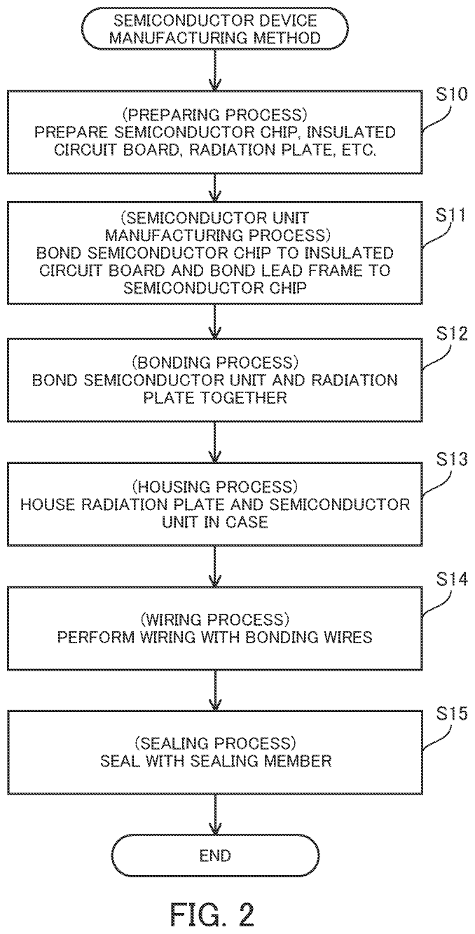

A method for manufacturing the semiconductor device 1 will now be described with reference to FIG. 2. FIG. 2 is a flow chart of a method for manufacturing the semiconductor device according to the first embodiment. First a preparing process for preparing parts needed for the semiconductor device 1 is performed (step S10). The semiconductor chip 4, the insulated circuit board 3, the lead frame 5, and the radiation plate 6 are taken as examples of parts needed for the semiconductor device 1. Furthermore, a case, a sealing member, and the like may be prepared.

Next, the semiconductor chip 4 is bonded to the prepared insulated circuit board 3. Furthermore, the lead frame 5 is bonded to the semiconductor chip 4. By doing so, a semiconductor unit manufacturing process for manufacturing the semiconductor unit 2 is performed (step S11). In the semiconductor unit manufacturing process, the semiconductor chip 4 is bonded to the insulated circuit board 3 with the bonding member 7b and the lead frame 5 is bonded to the semiconductor chip 4 with the bonding member 7c. The details of the semiconductor unit manufacturing process will be described later. Next, a bonding process for bonding the semiconductor unit 2 manufactured in this way and the radiation plate 6 together is performed (step S12). The details of the bonding process will be described later.

Next, a housing process for housing the radiation plate 6 and the semiconductor unit 2 bonded together in this way in a case is performed (step S13). Next, a wiring process for performing wiring by electrically connecting with bonding wires the semiconductor chip 4 and the insulated circuit board 3 of the semiconductor unit 2 housed in the case (step S14). The housing process may be performed after the wiring process is performed. Finally, a sealing process for sealing with a sealing member the semiconductor unit 2 over the radiation plate 6 housed in the case is performed (step S15). By performing the above processes, the semiconductor device 1 (except the bonding wires, the sealing member, and the case) illustrated in FIG. 1 is obtained.

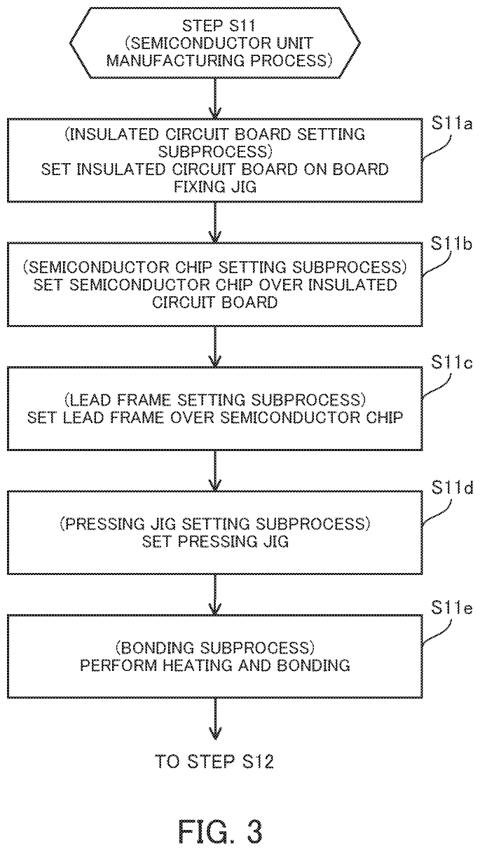

The semiconductor unit manufacturing process performed in step S11 of the flow chart of FIG. 2 will now be described with reference to FIG. 3. FIG. 3 is a flow chart of the semiconductor unit manufacturing process included in the method for manufacturing the semiconductor device according to the first embodiment.

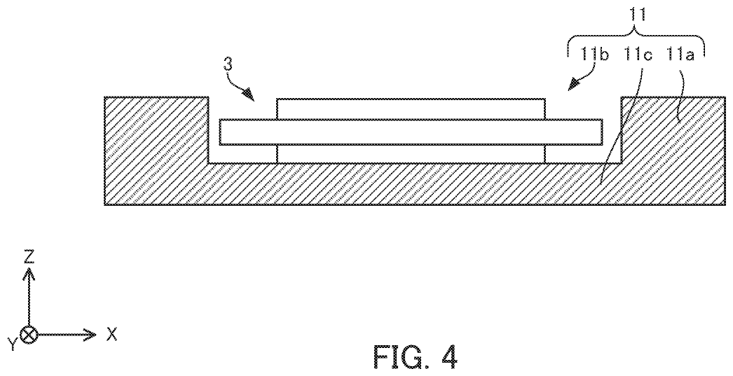

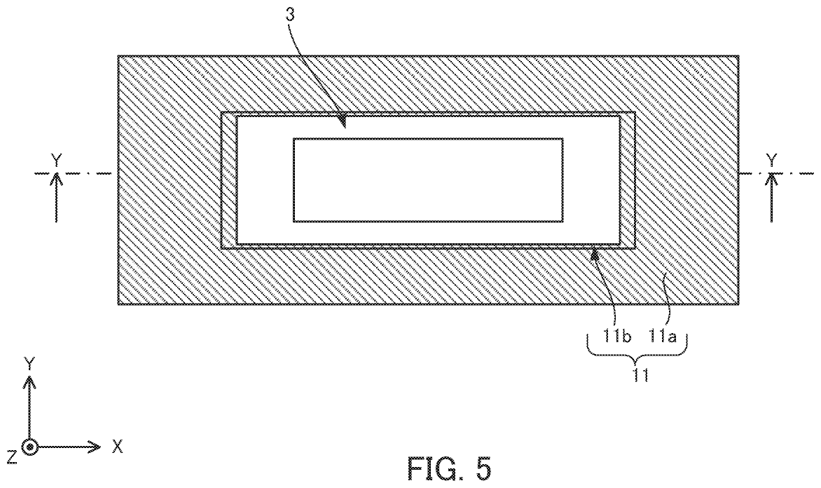

First, a setting subprocess for setting the insulated circuit board 3 on a board fixing jig 11 is performed (step S11a). Step S11a will be described with reference to FIG. 4 and FIG. 5. FIG. 4 is a sectional view illustrative of an insulated circuit board setting subprocess included in the semiconductor unit manufacturing process included in the method for manufacturing the semiconductor device according to the first embodiment. FIG. 5 is a plan view illustrative of the insulated circuit board setting subprocess included in the semiconductor unit manufacturing process included in the method for manufacturing the semiconductor device according to the first embodiment. FIG. 4 is a sectional view taken along the dot-dash line Y-Y of FIG. 5.

The board fixing jig 11 is used for locating the insulated circuit board 3 in a determined position and fixing it. The board fixing jig 11 includes a frame portion 11a and a bottom portion 11c. The bottom portion 11c has the shape of a flat plate and has area larger than that of the insulated circuit board 3 in plan view. The frame portion 11a is integrally formed with the front surface of the bottom portion 11c. The frame portion 11a surrounds in plan view a concave fixing area 11b corresponding to the shape (rectangular shape) of the insulated circuit board 3. It is desirable that the height of the fixing area 11b be approximately equal to that of the insulated circuit board 3.

As illustrated in FIG. 4 and FIG. 5, the insulated circuit board 3 is set in the fixing area 11b of the board fixing jig 11. This suppresses the positional deviation of the insulated circuit board 3 in the X direction and the Y direction (in the horizontal direction). Furthermore, at this time, the upper surface of the frame portion 11a of the board fixing jig 11 is flush with the upper surface of the insulated circuit board 3 (upper surface of the circuit pattern 3b). As a result, a chip positioning jig 12 described later is properly located on the frame portion 11a and the insulated circuit board 3.

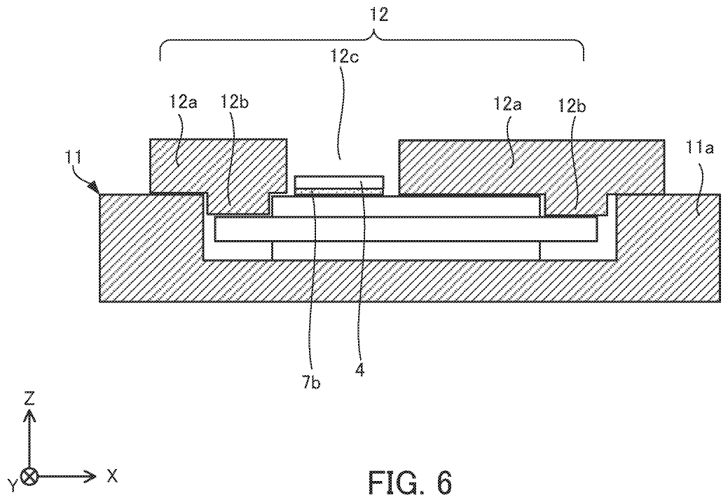

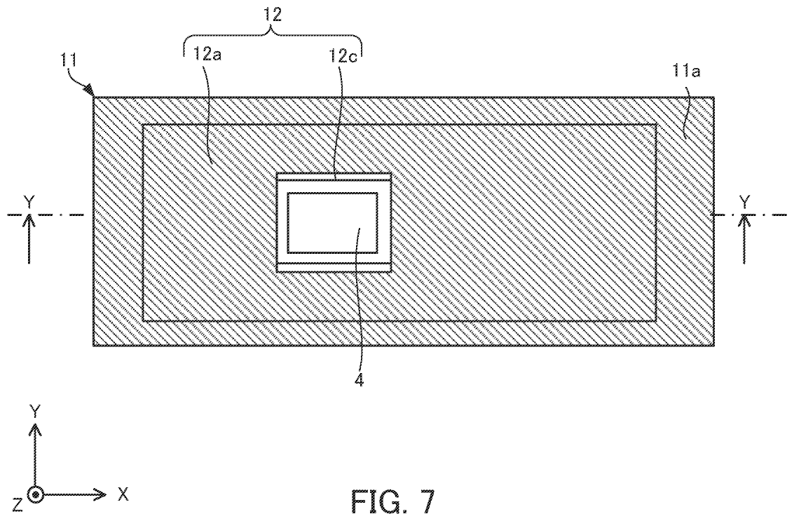

Next, a setting subprocess for setting the semiconductor chip 4 over the insulated circuit board 3 is performed (step S11b). Step S11b will be described with reference to FIG. 6 and FIG. 7. FIG. 6 is a sectional view illustrative of the semiconductor chip setting subprocess included in the semiconductor unit manufacturing process included in the method for manufacturing the semiconductor device according to the first embodiment. FIG. 7 is a plan view illustrative of the semiconductor chip setting subprocess included in the semiconductor unit manufacturing process included in the method for manufacturing the semiconductor device according to the first embodiment. FIG. 6 is a sectional view taken along the dot-dash line Y-Y of FIG. 7.

The chip positioning jig 12 is set on the board fixing jig 11 and the insulated circuit board 3 in step S11a. The chip positioning jig 12 includes a chip frame portion 12a including a chip opening portion 12c and a fixing portion 12b. The chip frame portion 12a has the shape of a flat plate. The chip opening portion 12c is formed in the chip frame portion 12a so that when the chip positioning jig 12 is located with respect to the board fixing jig 11, the chip opening portion 12c will be opposed to a position on the insulated circuit board 3 over which the semiconductor chip 4 is mounted.

The fixing portion 12b is formed on the back surface of the chip frame portion 12a. A section of the fixing portion 12b is convex so that when the chip positioning jig 12 is located with respect to the board fixing jig 11, the fixing portion 12b will fit in a gap between the frame portion 11a of the board fixing jig 11 and the circuit pattern 3b. The fixing portion 12b is formed circularly and continuously on the back surface of the chip frame portion 12a so that the fixing portion 12b will fit in a gap between the outside of the circuit pattern 3b of the insulated circuit board 3 and the frame portion 11a.

The above chip positioning jig 12 is mounted on the board fixing jig 11 and the insulated circuit board 3. As illustrated in FIG. 6 and FIG. 7, the semiconductor chip 4 is set through the chip opening portion 12c over the insulated circuit board 3 (circuit pattern 3b) with the bonding member 7b therebetween. The presence of the chip opening portion 12c of the chip positioning jig 12 suppresses the movement (deviation) of the semiconductor chip 4 in the horizontal direction (in the X direction and the Y direction). At this time, it is desirable that clearance between an edge portion of the chip opening portion 12c and an edge portion of the semiconductor chip 4 be more than or equal to 0.30 mm and less than or equal to 1.00 mm.

Furthermore, the back surface of the chip positioning jig 12 (chip frame portion 12a) is located so as to cover an area (protective area) of the circuit pattern 3b except a mounting area over which the semiconductor chip 4 is located. Because the chip positioning jig 12 covers the protective area of the circuit pattern 3b, scattering of the bonding member 7b used for bonding the circuit pattern 3b and the semiconductor chip 4 is suppressed.

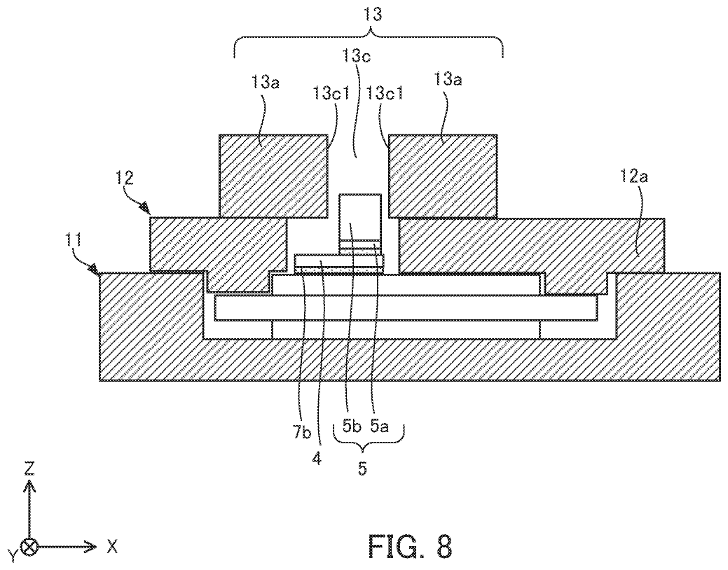

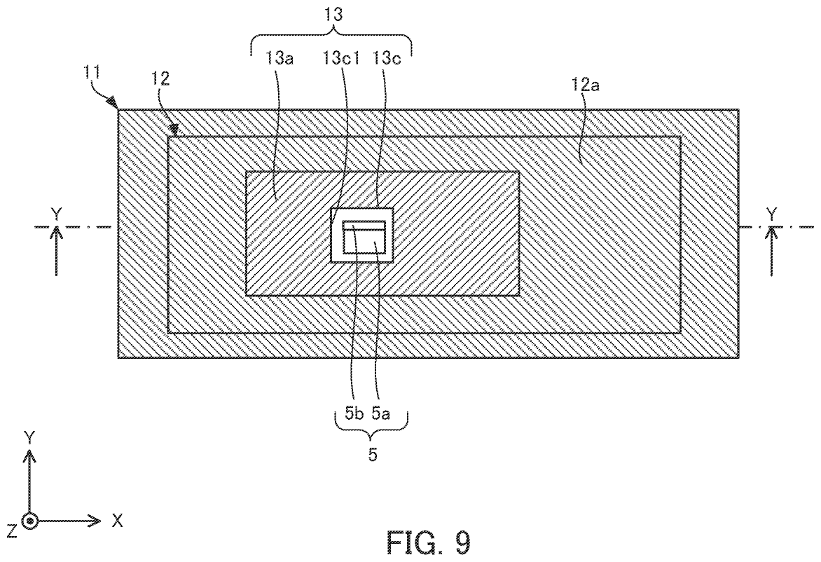

Next, a setting subprocess for setting the lead frame 5 over the semiconductor chip 4 is performed (step S11c). Step S11c will be described with reference to FIG. 8 and FIG. 9. FIG. 8 is a sectional view illustrative of a lead frame setting subprocess included in the semiconductor unit manufacturing process included in the method for manufacturing the semiconductor device according to the first embodiment. FIG. 9 is a plan view illustrative of the lead frame setting subprocess included in the semiconductor unit manufacturing process included in the method for manufacturing the semiconductor device according to the first embodiment. FIG. 8 is a sectional view taken along the dot-dash line Y-Y of FIG. 9.

A lead frame positioning jig 13, which also functions as a guide jig, is located on the chip positioning jig 12. The lead frame positioning jig 13 may be a weight. The lead frame positioning jig 13 includes a lead frame frame portion 13a including a lead frame opening portion 13c which functions as a guide hole. The lead frame frame portion 13a has the shape of a flat plate. The lead frame opening portion 13c is formed in the lead frame frame portion 13a. When the lead frame positioning jig 13 is located with respect to the chip positioning jig 12, the lead frame opening portion 13c is opposed to the position of the main electrode of the semiconductor chip 4 over which the lead frame 5 is mounted. For example, the lead frame opening portion 13c is rectangular in plan view. The lead frame opening portion 13c is surrounded by a lead frame inner wall portion 13c1 on all sides. Accordingly, the lead frame positioning jig 13 seals in plan view everything except the lead frame 5. Furthermore, the size of the lead frame positioning jig 13 may be such that it is located on the chip positioning jig 12 in plan view. The bonding portion 5a of the lead frame 5 is located through the lead frame opening portion 13c of the lead frame positioning jig 13 over the semiconductor chip 4 with the bonding member 7c therebetween.

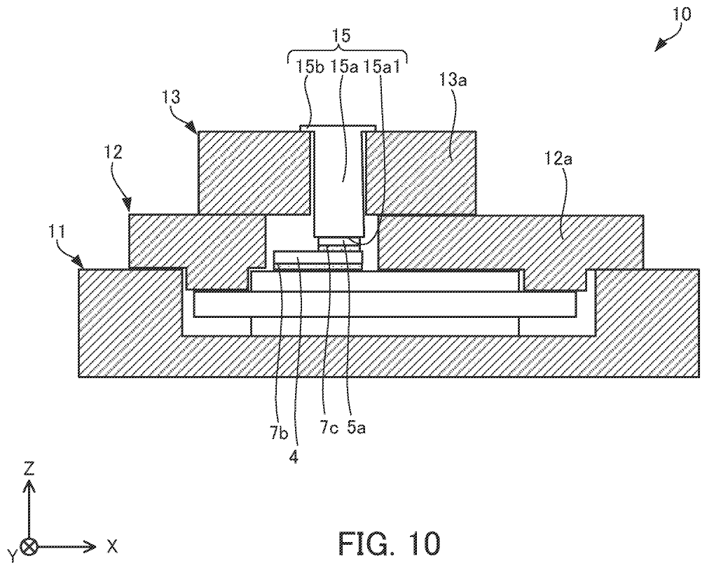

Next, a setting subprocess for setting a pressing jig 15 in the lead frame opening portion 13c of the lead frame positioning jig 13 is performed (step S11d). Step S11d will be described with reference to FIG. 10. FIG. 10 is a sectional view illustrative of a pressing jig setting subprocess included in the semiconductor unit manufacturing process included in the method for manufacturing the semiconductor device according to the first embodiment. FIG. 10 is a sectional view corresponding to FIG. 8.

The pressing jig 15 is inserted into the lead frame opening portion 13c of the lead frame positioning jig 13 to set the pressing jig 15. The pressing jig 15 includes a pressing body portion 15a and a locking portion 15b. The pressing body portion 15a has the shape of a pillar. The shape of the pressing body portion 15a may correspond in plan view to that of the lead frame opening portion 13c. The pressing body portion 15a may have the shape of a prism or a cylinder according to the shape of the lead frame opening portion 13c. The end of the pressing body portion 15a has a pressing surface 15a1, which is a pressing portion. When the pressing jig 15 is set, the pressing surface 15a1 comes in contact with the front surface of the bonding portion 5a of the lead frame 5. As illustrated in FIG. 10, the pressing surface 15a1, which is a pressing portion, is a flat surface parallel with the front surface of the bonding portion 5a. The end of the pressing body portion 15a need only have the pressing surface 15a1. The end of the pressing body portion 15a may have a shape obtained by cutting an end portion having the shape of a spire perpendicularly to the direction in which the pressing body portion 15a extends. Alternatively, it may be that the pressing portion will not include a flat surface. That is to say, the pressing portion may be semispherical. Furthermore, the locking portion 15b is formed above the pressing surface 15a1 of the pressing body portion 15a. The locking portion 15b is formed circularly and continuously along an outer peripheral portion of an end portion of the pressing body portion 15a on the opposite side of the pressing surface 15a1. When the pressing jig 15 is set in the lead frame opening portion 13c, the locking portion 15b is locked on the lead frame opening portion 13c. The locking portion 15b need only prevent the pressing jig 15 from excessively falling in. It may be that the locking portion 15b will not be formed circularly or continuously along the outer peripheral portion of the end portion of the pressing body portion 15a on the opposite side of the pressing surface 15a1. The locking portion 15b may be formed circularly and discontinuously along the outer peripheral portion of the end portion of the pressing body portion 15a on the opposite side of the pressing surface 15a1.

When the above pressing jig 15 is set in the lead frame opening portion 13c, the pressing surface 15a1 comes in contact with the front surface of the bonding portion 5a of the lead frame 5. The pressing jig 15 presses the bonding portion 5a to the side of the insulated circuit board 3 with the pressing surface 15a1 by its own weight. However, the locking portion 15b suppresses the pressing jig 15 excessively pressing the bonding portion 5a. This prevents damage to the main electrode on the front surface of the semiconductor chip 4.

As described above, the board fixing jig 11, the chip positioning jig 12, the lead frame positioning jig 13, and the pressing jig 15 make up a manufacturing jig set 10. The board fixing jig 11, the chip positioning jig 12, and the lead frame positioning jig 13 included in the manufacturing jig set 10 may be made of a material, such as carbon, having high heat resistance.

Next, a bonding subprocess is performed (step S11e). Heating is performed in a state in which the bonding portion 5a of the lead frame 5 is pressed to the side of the insulated circuit board 3 by the pressing jig 15. As a result, the bonding members 7b and 7c melt. Furthermore, the semiconductor chip 4 warps because of the difference in thermal expansion coefficient between the semiconductor chip 4 and the insulated circuit board 3. At this time, the semiconductor chip 4 is pressed by the pressing jig 15 with the bonding portion 5a therebetween. Accordingly, a warp of the semiconductor chip 4 is corrected.

At this time, positional deviations of the insulated circuit board 3 in the X direction and the Y direction are suppressed by the board fixing jig 11 and positional deviations of the insulated circuit board 3 in the Z direction are suppressed by the chip positioning jig 12. Furthermore, positional deviations of the semiconductor chip 4 in the X direction and the Y direction are suppressed by the chip positioning jig 12. In addition, positional deviations of the semiconductor chip 4 and the lead frame 5 in the Z direction are suppressed by the pressing jig 15.

Moreover, the circuit pattern 3b, the semiconductor chip 4, and the bonding portion 5a are approximately parallel with one another. Accordingly, the thickness of the bonding member 7b between the insulated circuit board 3 and the semiconductor chip 4 and the thickness of the bonding member 7c between the semiconductor chip 4 and the bonding portion 5a are kept approximately uniform. When the molten bonding members 7b and 7c are solidified, the insulated circuit board 3 and the semiconductor chip 4 are bonded with the bonding member 7b and the semiconductor chip 4 and the bonding portion 5a of the lead frame 5 are bonded with the bonding member 7c. The bonding members 7b and 7c are uniform in thickness. As a result, the semiconductor chip 4 and the lead frame 5 are properly connected. Stable electrical bonding is realized between the semiconductor chip 4 and the lead frame 5 and the occurrence of an electrical failure is suppressed. At this time, the locking portion 15b suppresses the pressing jig 15 excessively pressing the semiconductor chip 4. This prevents damage to the main electrode of the semiconductor chip 4.

After the semiconductor unit manufacturing process is performed in the above step S11 of the flow chart of FIG. 2, the pressing jig 15, the lead frame positioning jig 13, and the chip positioning jig 12 are removed in order and the board fixing jig 11 is taken away. As a result, the semiconductor unit 2 is obtained.

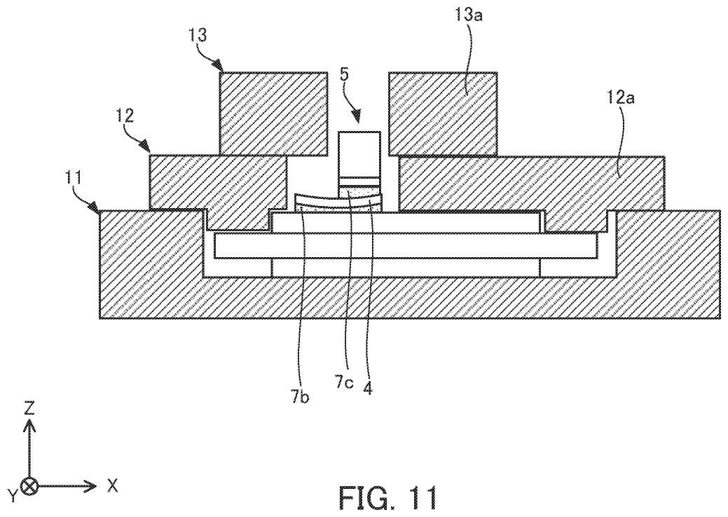

A bonding subprocess in which the pressing jig 15 is not used will be described as a reference example with reference to FIG. 11. FIG. 11 is a sectional view illustrative of a semiconductor unit manufacturing process included in a method for manufacturing a semiconductor device taken as a reference example. FIG. 11 illustrates a case where the pressing jig 15 is excluded from FIG. 10.

In this case, heating is performed. This is the same with the above step S11e. As a result, the bonding members 7b and 7c melt. Furthermore, as stated above, the semiconductor chip 4 warps because of the difference in thermal expansion coefficient between the semiconductor chip 4 and the insulated circuit board 3. When the molten bonding members 7b and 7c are solidified in this state, the thickness of the bonding members 7b and 7c becomes non-uniform, as illustrated in FIG. 11, according to a warp of the semiconductor chip 4. Stable electrical bonding is not realized between the semiconductor chip 4 and the lead frame 5 bonded in this way and an electrical failure may occur.

In the first embodiment, the semiconductor chip 4 is pressed by the pressing jig 15 with the bonding portion 5a therebetween. As a result, the thickness of the bonding member 7b between the insulated circuit board 3 and the semiconductor chip 4 and the thickness of the bonding member 7c between the semiconductor chip 4 and the bonding portion 5a are kept approximately uniform. The bonding members 7b and 7c are solidified in this state and the semiconductor chip 4 and the lead frame 5 are properly connected mechanically and electrically.

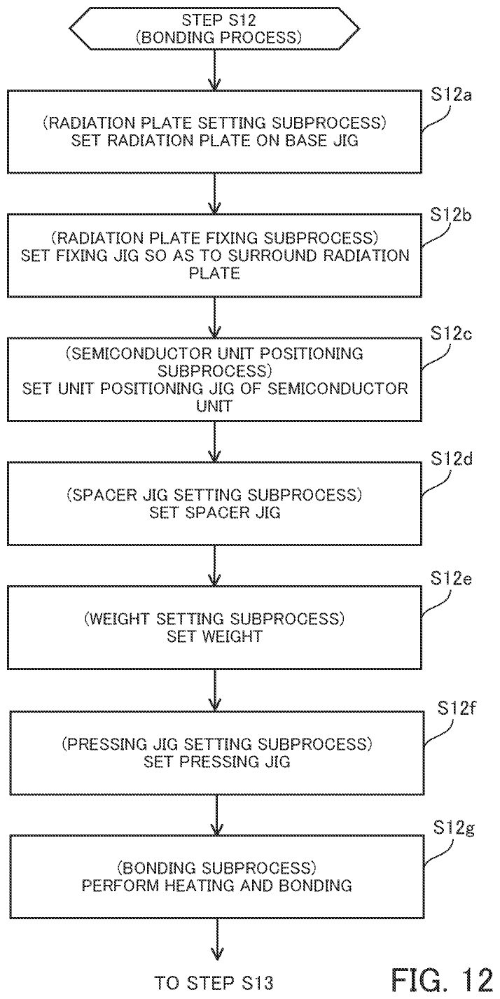

Next, the bonding process performed in step S12 of the flow chart of FIG. 2 will be described with reference to FIG. 12. FIG. 12 is a flow chart of a bonding process included in the method for manufacturing the semiconductor device according to the first embodiment.

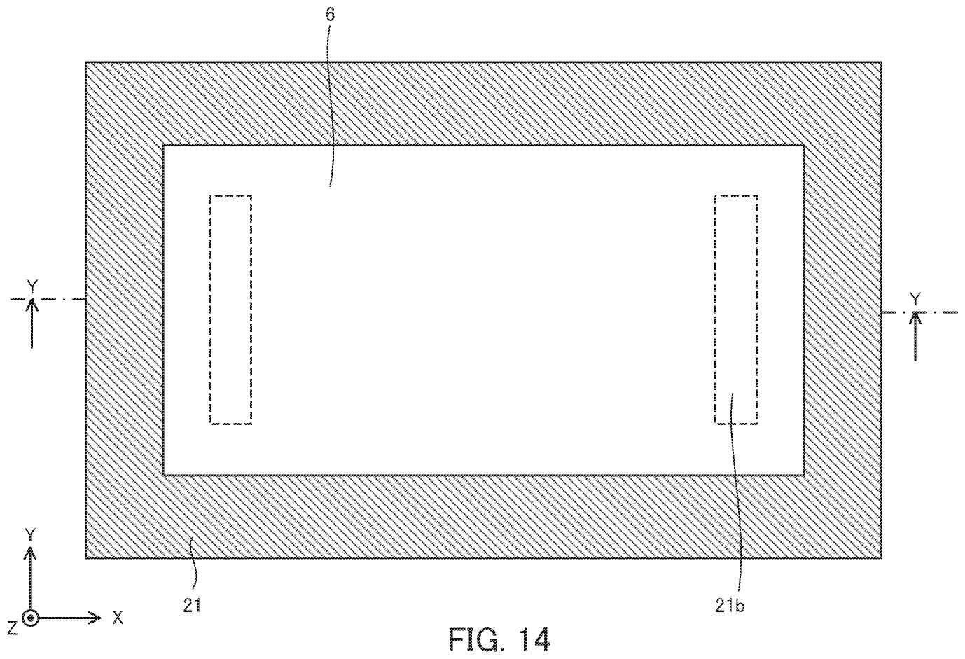

First, a setting subprocess for setting the radiation plate 6 on a base jig 21 is performed (step S12a). Step S12a will be described with reference to FIG. 13 and FIG. 14. FIG. 13 is a sectional view illustrative of a radiation plate setting subprocess included in the bonding process included in the method for manufacturing the semiconductor device according to the first embodiment. FIG. 14 is a plan view illustrative of the radiation plate setting subprocess included in the bonding process included in the method for manufacturing the semiconductor device according to the first embodiment. FIG. 13 is a sectional view taken along the dot-dash line Y-Y of FIG. 14. Furthermore, FIG. 14 indicates the position of a fixing member 21b by a dashed line.

The base jig 21 is used for fixing the radiation plate 6 located in a determined position. The base jig 21 has the shape of a flat plate and the area of the base jig 21 is larger in plan view than that of the radiation plate 6. A groove portion 21a may be formed in the front surface of the base jig 21. For example, the groove portion 21a is formed in parallel with short sides of the base jig 21 and does not pierce the base jig 21. A fixing groove 6a which is equal in shape to the groove portion 21a is also formed in a position corresponding to the groove portion 21a in the back surface of the radiation plate 6. A fixing member 21b is fitted into the groove portion 21a of the base jig 21 and the fixing groove 6a of the radiation plate 6 is located on the fixing member 21b. The shape of the fixing member 21b corresponds to that of the groove portion 21a. As a result, the radiation plate 6 is fixed onto the base jig 21 and positional deviations of the radiation plate 6 in the X direction and the Y direction are prevented.

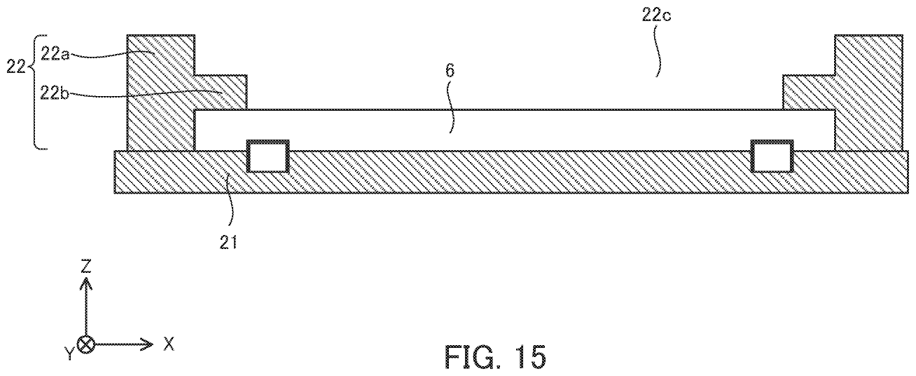

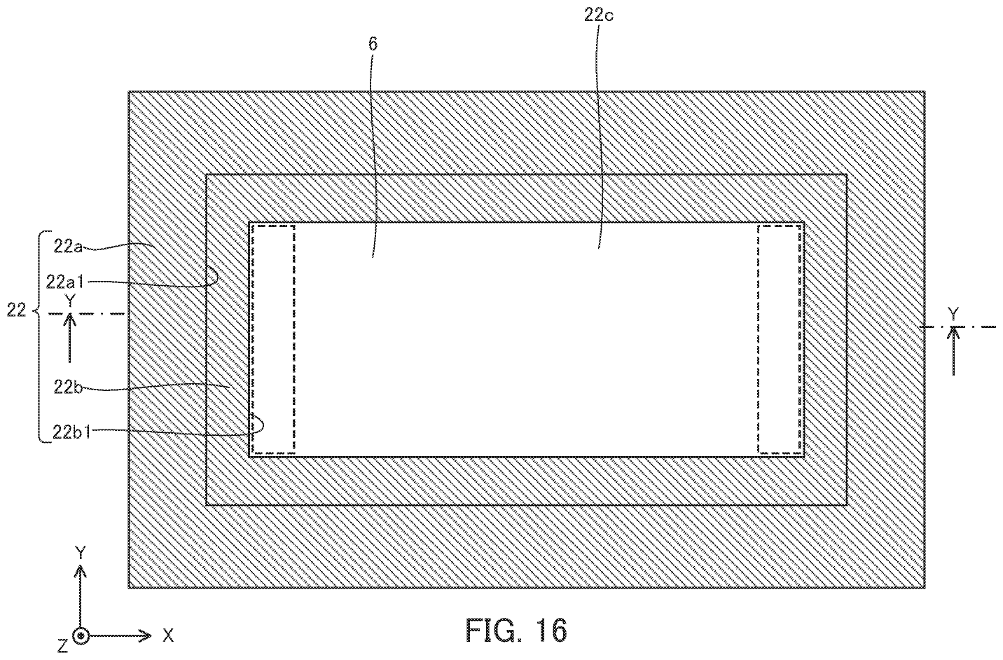

Next, a fixing subprocess for fixing the radiation plate 6 is performed (step S12b). Step S12b will be described with reference to FIG. 15 and FIG. 16. FIG. 15 is a sectional view illustrative of a radiation plate fixing subprocess included in the bonding process included in the method for manufacturing the semiconductor device according to the first embodiment. FIG. 16 is a plan view illustrative of the radiation plate fixing subprocess included in the bonding process included in the method for manufacturing the semiconductor device according to the first embodiment.

As illustrated in FIG. 15 and FIG. 16, a fixing jig 22 is set on the base jig 21 so as to surround the radiation plate 6. The fixing jig 22 includes a first frame portion 22a and a first protruding portion 22b. The first frame portion 22a has the shape of a frame in plan view. The first frame portion 22a includes a first inner wall portion 22a1 so as to surround the entire perimeter of the radiation plate 6. The first inner wall portion 22a1 has on its four sides flat surfaces which are in contact with the entire perimeter of the radiation plate 6. The first protruding portion 22b protrudes perpendicularly from the first inner wall portion 22a1 and forms a continuous circle along the first inner wall portion 22a1. The first protruding portion 22b is formed in a position corresponding to the thickness of the radiation plate 6 from the lower surface of the first frame portion 22a. When the above fixing jig 22 is fixed to the radiation plate 6 on the base jig 21, the first frame portion 22a of the fixing jig 22 fits on the sides of the radiation plate 6 and the front surface of an outer peripheral portion of the radiation plate 6 is in contact with the first protruding portion 22b, as illustrated in FIG. 15 and FIG. 16. This prevents positional deviations of the radiation plate 6 in the Z direction on the base jig 21. Furthermore, at this time, a first opening area 22c is surrounded by a first protruding inner wall portion 22b1 inside the first protruding portion 22b.

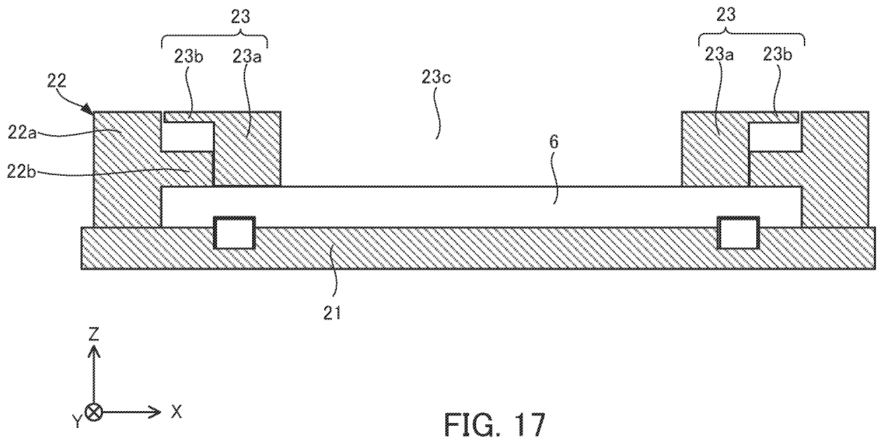

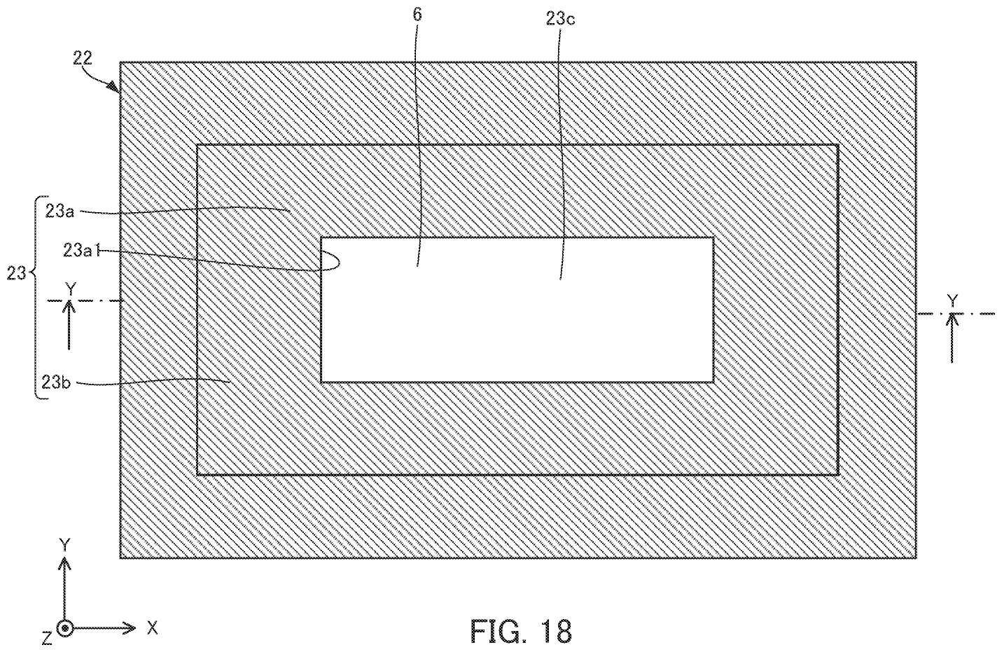

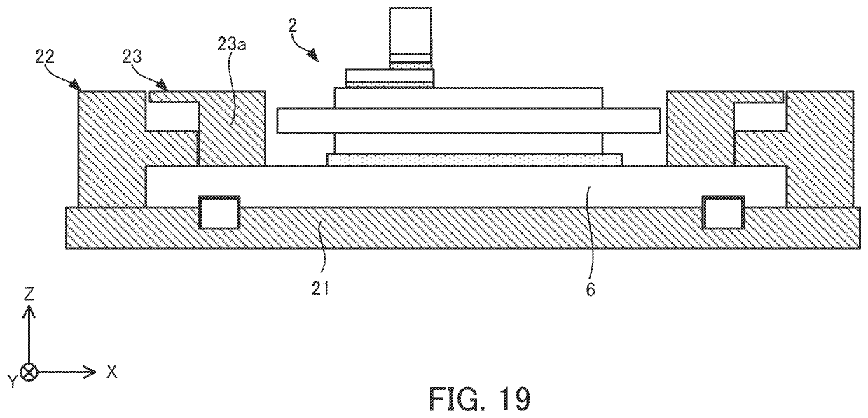

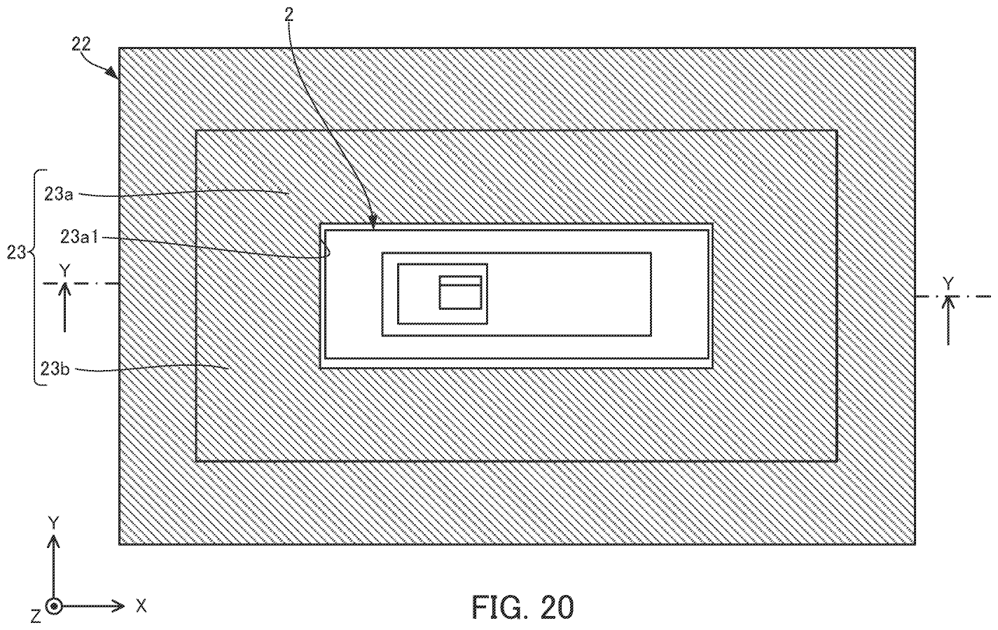

Next, a subprocess for positioning the semiconductor unit 2 is performed (step S12c). Step S12c will be described with reference to FIGS. 17 through 20. FIG. 17 and FIG. 19 are sectional views illustrative of a semiconductor unit positioning subprocess included in the bonding process included in the method for manufacturing the semiconductor device according to the first embodiment. FIG. 18 and FIG. 20 are plan views illustrative of the semiconductor unit positioning subprocess included in the bonding process included in the method for manufacturing the semiconductor device according to the first embodiment. FIG. 17 and FIG. 19 are sectional views taken along the dot-dash lines Y-Y of FIGS. 18 and 20, respectively.

As illustrated in FIG. 17 and FIG. 18, a unit positioning jig 23 is located on the radiation plate 6 in the first opening area 22c of the fixing jig 22. The unit positioning jig 23 includes a second frame portion 23a and a second protruding portion 23b. The second frame portion 23a has the shape of a frame in plan view. The second frame portion 23a includes a second inner wall portion 23a1. The second inner wall portion 23a1 surrounds a second opening area 23c on all sides. The height of the second frame portion 23a corresponds to the length from the front surface of the radiation plate 6 to the front surface of the first frame portion 22a of the fixing jig 22.

The second protruding portion 23b is formed on the second frame portion 23a so that when the fixing jig 22 is located on the radiation plate 6, the second protruding portion 23b will close a gap between the second frame portion 23a and the first frame portion 22a. The second protruding portion 23b is formed on the second frame portion 23a so that when the fixing jig 22 is located on the radiation plate 6, the second protruding portion 23b will flush with the front surfaces of the second frame portion 23a and the first frame portion 22a. The thickness of the second protruding portion 23b is, at the most, the height from the front surface of the first protruding portion 22b to the front surface of the first frame portion 22a.

Furthermore, as illustrated in FIG. 19 and FIG. 20, the semiconductor unit 2 is located over the radiation plate 6 with the bonding member 7a therebetween through the unit positioning jig 23 located in this way. At this time, the front surface of the insulated circuit board 3 over the bonding member 7a is flush with the second frame portion 23a and the first frame portion 22a.

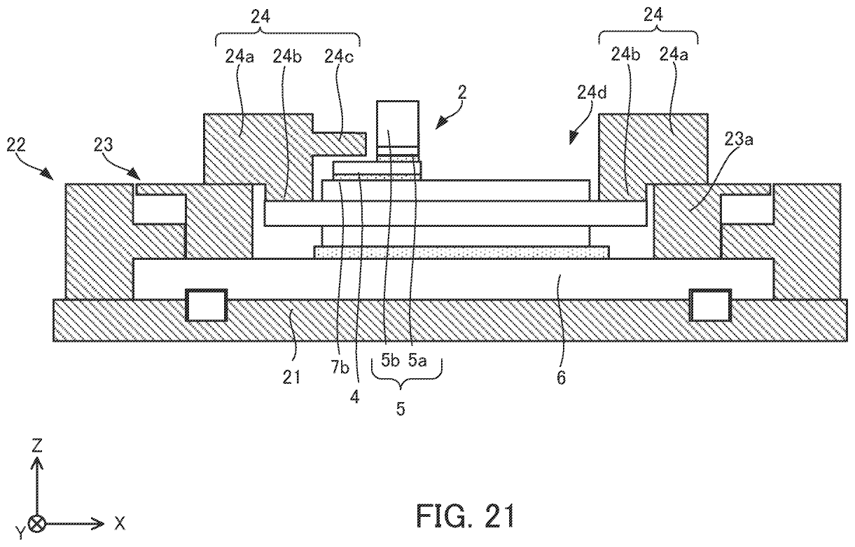

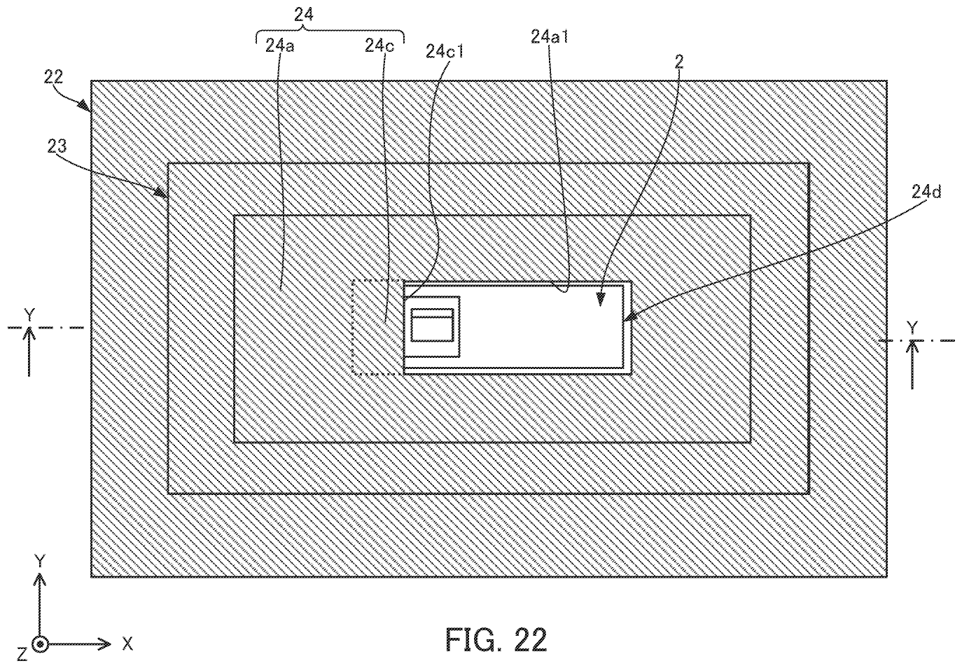

Next, a setting subprocess for setting a spacer jig 24 on the unit positioning jig 23 and the insulated circuit board 3 (step S12d). Step S12d will be described with reference to FIG. 21 and FIG. 22. FIG. 21 is a sectional view illustrative of a spacer jig setting subprocess included in the bonding process included in the method for manufacturing the semiconductor device according to the first embodiment. FIG. 22 is a plan view illustrative of the spacer jig setting subprocess included in the bonding process included in the method for manufacturing the semiconductor device according to the first embodiment. FIG. 21 is a sectional view taken along the dot-dash line Y-Y of FIG. 22.

The spacer jig 24 includes a third frame portion 24a including a spacer opening portion 24d, a positioning fixing portion 24b, and a guide portion 24c. The third frame portion 24a has the shape of a flat plate. The third frame portion 24a includes a third inner wall portion 24a1. When the spacer jig 24 is located with respect to the unit positioning jig 23, the third inner wall portion 24a1 surrounds the circuit pattern 3b of the insulated circuit board 3. That is to say, the third inner wall portion 24a1 surrounds the spacer opening portion 24d on all sides. The spacer opening portion 24d includes components over the circuit pattern 3b of the semiconductor unit 2.

The positioning fixing portion 24b is formed on the back surface of the third frame portion 24a. The positioning fixing portion 24b is flush with the third inner wall portion 24a1 of the third frame portion 24a. A section of the positioning fixing portion 24b is convex so that when the spacer jig 24 is located with respect to the unit positioning jig 23, the positioning fixing portion 24b will fit in a gap between the second frame portion 23a of the unit positioning jig 23 and the circuit pattern 3b. The positioning fixing portion 24b is formed circularly and continuously on the back surface of the third frame portion 24a so as to fit in a gap between the outside of the circuit pattern 3b of the insulated circuit board 3 and the second frame portion 23a. Accordingly, the width (in the ±X directions and the ±Y directions) of the positioning fixing portion 24b corresponds to width by which the insulating plate 3a of the insulated circuit board 3 juts out from the circuit pattern 3b.

The guide portion 24c is formed so that a guide inner wall portion 24c1 will protrude from part of the third inner wall portion 24a1 of the third frame portion 24a. As illustrated in FIG. 21 and FIG. 22, when the spacer jig 24 is mounted on the unit positioning jig 23 and the insulated circuit board 3, the guide inner wall portion 24c1 of the guide portion 24c extends to a side portion of the lead frame 5.

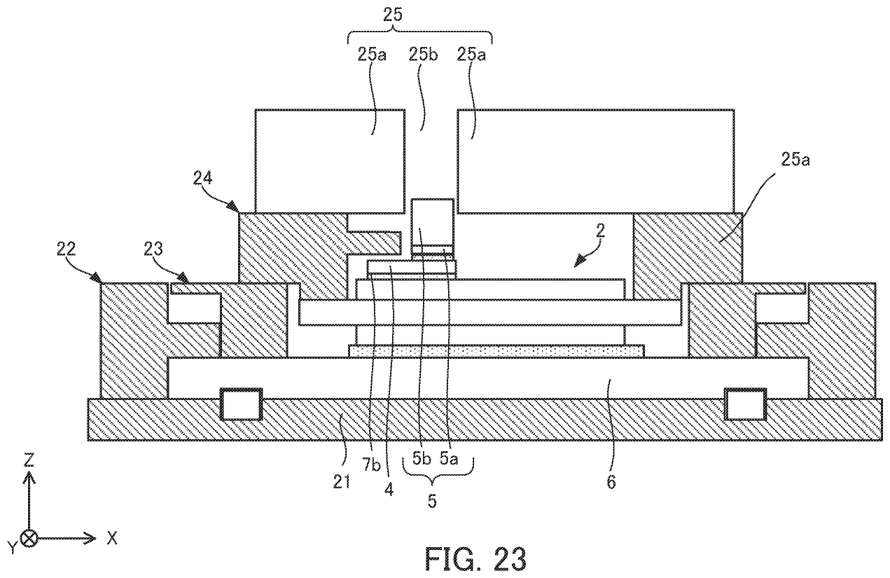

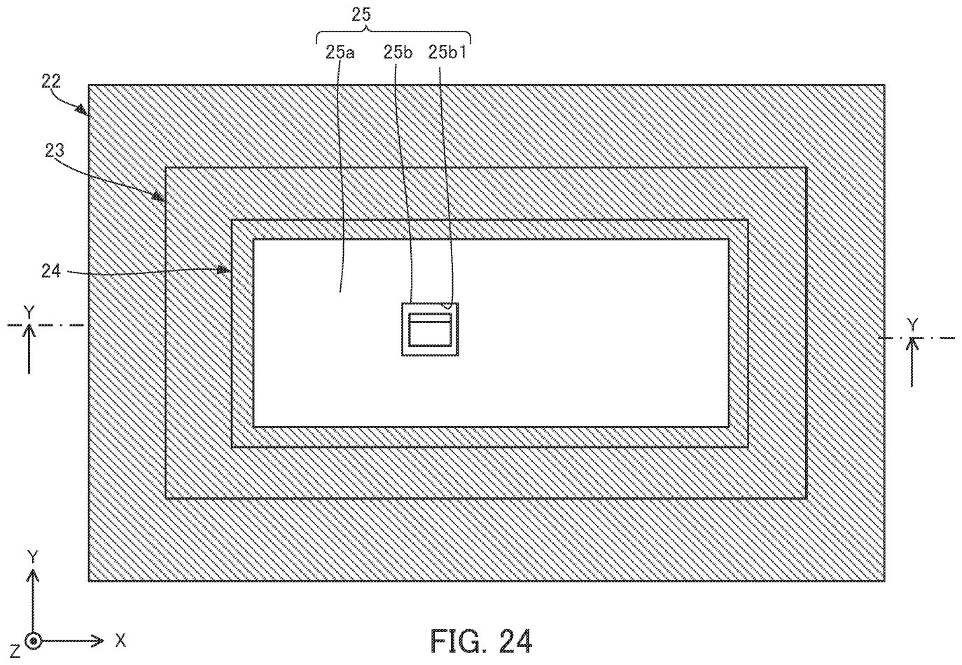

Next, a setting subprocess for setting a weight is performed (step S12e). Step S12e will be described with reference to FIG. 23 and FIG. 24. FIG. 23 is a sectional view illustrative of a weight setting subprocess included in the bonding process included in the method for manufacturing the semiconductor device according to the first embodiment. FIG. 24 is a plan view illustrative of the weight setting subprocess included in the bonding process included in the method for manufacturing the semiconductor device according to the first embodiment. FIG. 23 is a sectional view taken along the dot-dash line Y-Y of FIG. 24.

A weight 25 is located on the spacer jig 24. The weight 25 includes a body portion 25a and a guide hole 25b. The body portion 25a has the shape of a cube. The body portion 25a is made of, for example, stainless steel. The weight 25 need only have a determined weight. Furthermore, the weight 25 need only be higher than the lead frame 5 protruding from the front surface of the spacer jig 24. The guide hole 25b is formed in the body portion 25a so that when the weight 25 is located on the spacer jig 24, the guide hole 25b will correspond to the lead frame 5 (bonding portion 5a). The shape of the guide hole 25b in plan view corresponds to that of the pressing jig 15 in plan view. For example, the guide hole 25b is rectangular or circular in plan view. The guide hole 25b may be triangular in plan view. In FIG. 23 and FIG. 24, the guide hole 25b is rectangular and is surrounded on all sides by a guide inner wall portion 25b1.

As illustrated in FIG. 23 and FIG. 24, the above weight 25 is located on the spacer jig 24, the body portion 25a of the weight 25 is supported on the spacer jig 24 and the lead frame 5 is situated in the guide hole 25b. As a result, the semiconductor unit 2 is pressed to the side of the radiation plate 6 by the weight 25 with the spacer jig 24 therebetween.

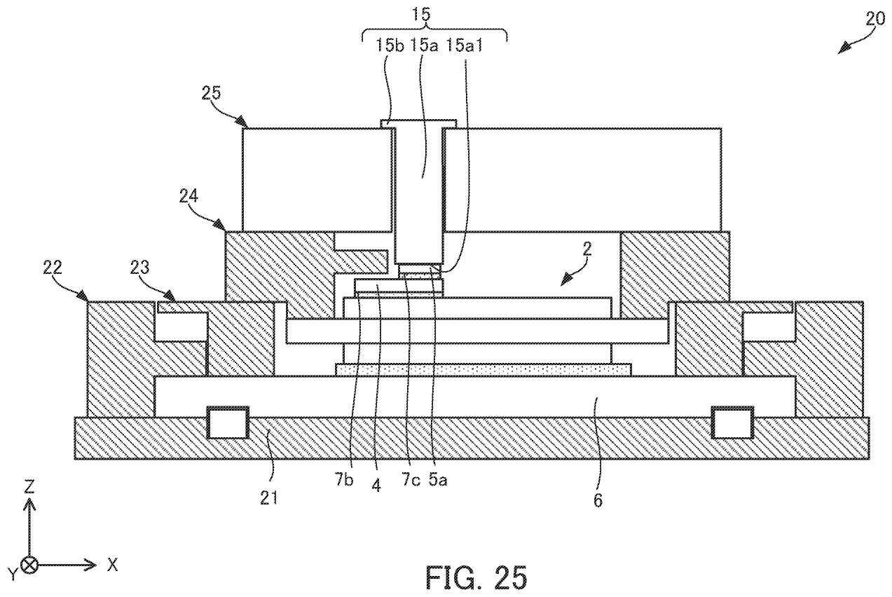

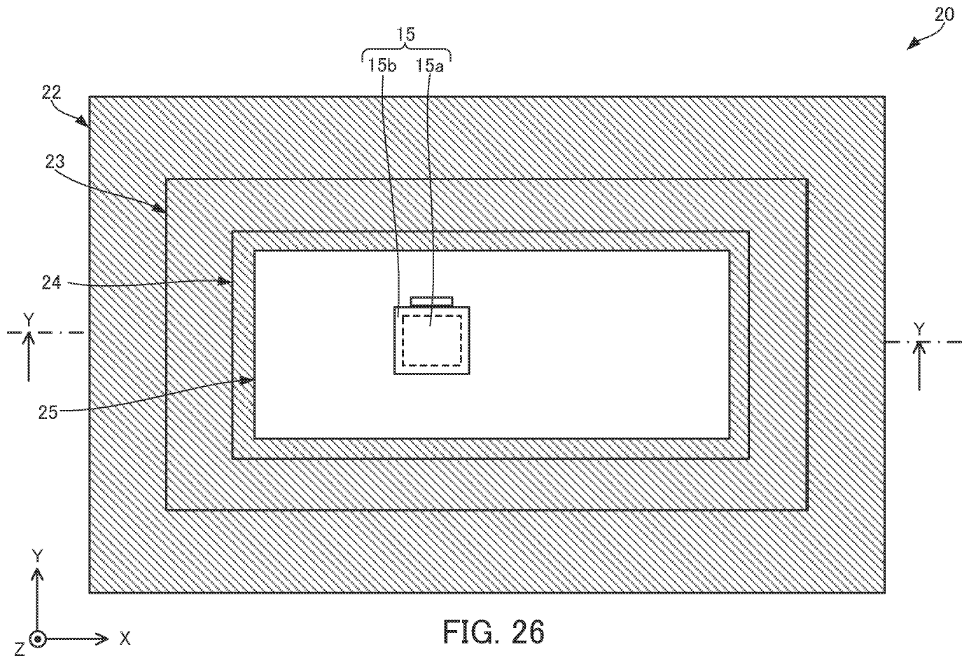

Next, a setting subprocess for setting a pressing jig is performed (step S12f). Step S12f will be described with reference to FIG. 25 and FIG. 26. FIG. 25 is a sectional view illustrative of a pressing jig setting subprocess included in the bonding process included in the method for manufacturing the semiconductor device according to the first embodiment. FIG. 26 is a plan view illustrative of the pressing jig setting subprocess included in the bonding process included in the method for manufacturing the semiconductor device according to the first embodiment. FIG. 25 is a sectional view taken along the dot-dash line Y-Y of FIG. 26.

As described in FIG. 10, the pressing jig 15 includes the pressing body portion 15a and the locking portion 15b. The pressing body portion 15a has the pressing surface 15a1 as a pressing portion at the end. As illustrated in FIG. 25 and FIG. 26, the pressing jig 15 is inserted into the guide hole 25b of the weight 25 to set the pressing jig 15. In this case, the pressing surface 15a1 is in contact with the front surface of the bonding portion 5a of the lead frame 5. The pressing jig 15 presses the bonding portion 5a to the side of the insulated circuit board 3 with the pressing surface 15a1 by its own weight. However, the locking portion 15b suppresses the pressing jig 15 excessively pressing the bonding portion 5a.

As has been described, the base jig 21, the fixing jig 22, the unit positioning jig 23, the spacer jig 24, the weight 25, and the pressing jig 15 make up a bonding jig set 20. The base jig 21, the fixing jig 22, the unit positioning jig 23, and the spacer jig 24 included in the bonding jig set 20 may be made of a material, such as carbon, having high heat resistance.

Next, a bonding subprocess is performed (step S12g). Heating is performed in a state in which the pressing jig 15 presses the bonding portion 5a of the lead frame 5 to the side of the insulated circuit board 3. As a result, the bonding member 7a melts. Furthermore, the bonding members 7b and 7c also melt again. At this time, the semiconductor chip 4 which warps because of the difference in thermal expansion coefficient between the semiconductor chip 4 and the insulated circuit board 3 is pressed by the pressing jig 15 to the side of the insulated circuit board 3. Accordingly, as described in FIG. 10, a warp of the semiconductor chip 4 is corrected.

Because the circuit pattern 3b, the semiconductor chip 4, and the bonding portion 5a of the lead frame 5 are approximately parallel with one another, at this time, the thickness of the bonding member 7a between the semiconductor unit 2 and the radiation plate 6 and the bonding members 7b and 7c is kept approximately uniform. When the molten bonding members 7a, 7b, and 7c are solidified, the insulated circuit board 3 and the semiconductor chip 4 are bonded with the bonding member 7b and the semiconductor chip 4 and the bonding portion 5a of the lead frame 5 are bonded with the bonding member 7c. At this time, the thickness of the bonding members 7b and 7c is also uniform. As a result, the semiconductor unit 2 in which the insulated circuit board 3 and the semiconductor chip 4 are bonded again and in which the semiconductor chip 4 and the lead frame 5 are bonded again is obtained again. Furthermore, the radiation plate 6 and the semiconductor unit 2 are bonded. Because the radiation plate 6 is pressed by the insulated circuit board 3, the bonding member 7a is thin and the thickness of the bonding member 7a is kept uniform.

After the above bonding process in step S12 of the flow chart of FIG. 2 is performed, the weight 25, the spacer jig 24, the unit positioning jig 23, and the fixing jig 22 are removed in order and the base jig 21 is taken away. By doing so, the semiconductor device 1 illustrated in FIG. 1 is obtained.

With the method for manufacturing the above semiconductor device 1, the insulated circuit board 3, the semiconductor chip 4 located over the circuit pattern 3b of the insulated circuit board 3 with the bonding member 7b therebetween, and the lead frame 5 including the bonding portion 5a located over the semiconductor chip 4 with the bonding member 7c therebetween are prepared. Next, the lead frame positioning jig 13 which the lead frame opening portion 13c pierces is located opposite the insulated circuit board 3 so that the lead frame opening portion 13c will correspond in plan view to the bonding portion 5a of the lead frame 5. Next, the pressing jig 15 having the shape of a pillar and having the pressing surface 15a1 at the end is inserted into the lead frame opening portion 13c and the bonding portion 5a of the lead frame 5 is pressed to the side of the insulated circuit board 3 with the pressing surface 15a1.

The semiconductor chip 4 is pressed in this way by the pressing jig 15 with the bonding portion 5a of the lead frame 5 therebetween. When heating is performed for bonding the bonding members 7b and 7c, the semiconductor chip 4 may warp because of the difference in thermal expansion coefficient between the semiconductor chip 4 and the insulated circuit board 3. Even in this case, the semiconductor chip 4 is pressed by the pressing jig 15 and a warp of the semiconductor chip 4 is corrected. Accordingly, the thickness of the bonding members 7b and 7c is made uniform and the semiconductor chip 4 and the lead frame 5 are properly connected. Stable electrical bonding is realized between the semiconductor chip 4 and the lead frame 5 and the occurrence of an electrical failure is suppressed. Furthermore, the same applies when the semiconductor unit 2 and the radiation plate 6 are bonded.

### Second Embodiment

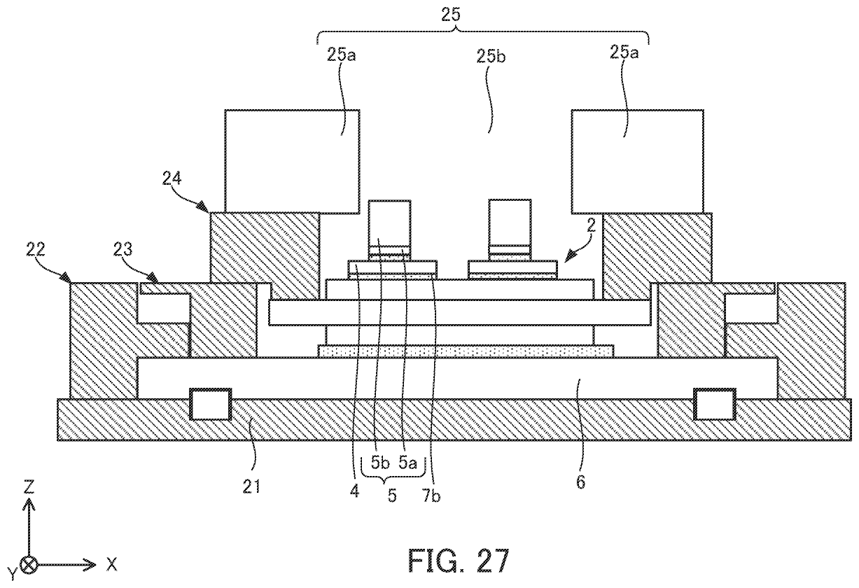

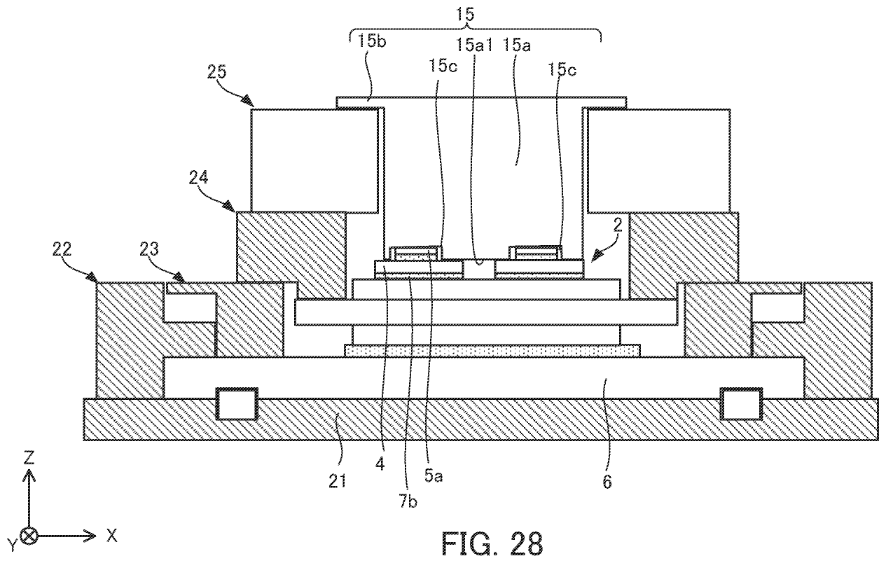

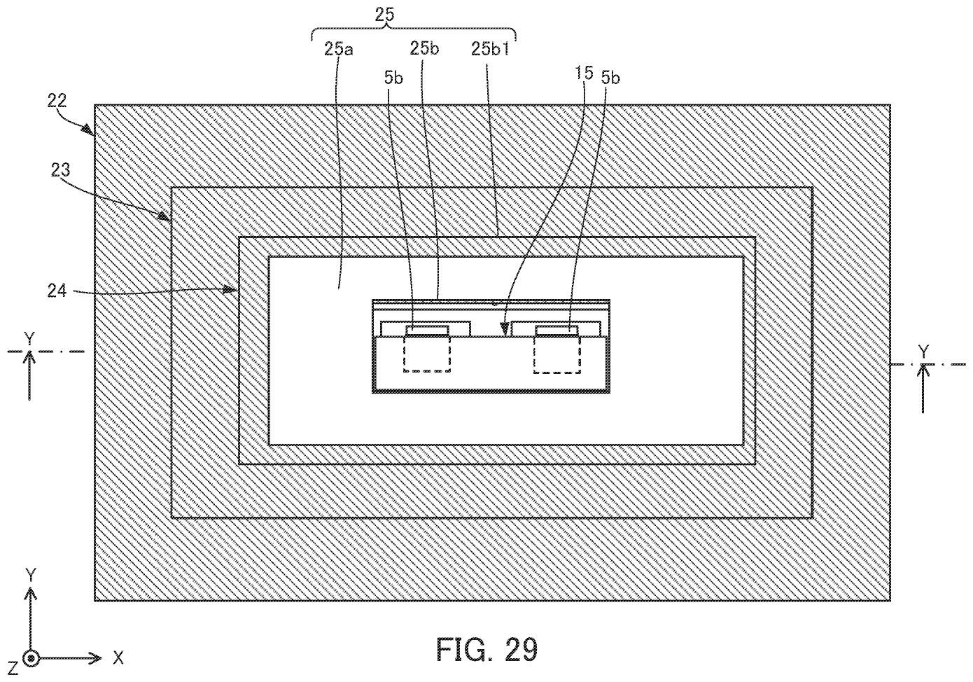

In a second embodiment, a case where a pressing jig different from that used in the first embodiment is used will be described with reference to FIGS. 27 through 29. FIG. 27 is a sectional view illustrative of a weight setting subprocess included in a bonding process included in a method for manufacturing a semiconductor device according to a second embodiment. FIG. 28 is a sectional view illustrative of a pressing jig setting subprocess included in the bonding process included in the method for manufacturing the semiconductor device according to the second embodiment. FIG. 29 is a plan view illustrative of the pressing jig setting subprocess included in the bonding process included in the method for manufacturing the semiconductor device according to the second embodiment. FIG. 28 is a sectional view taken along the dot-dash line Y-Y of FIG. 29.

The structure of a semiconductor unit 2 in the second embodiment is the same as that of the semiconductor unit 2 in the first embodiment. In this case, however, two lead frames 5 are located. The semiconductor device according to the second embodiment is also manufactured in accordance with the flow chart of FIG. 2. Furthermore, a pressing jig is used in the same way in steps S11 and S12. A case where a pressing jig is used in step S12 will now be described.

In step S11, the semiconductor unit 2 in which the two lead frames 5 are bonded is manufactured. In step S12, a setting subprocess for setting a radiation plate 6 on a base jig 21 (step S12a), a fixing subprocess for fixing the radiation plate 6 (step S12b), a subprocess for positioning the semiconductor unit 2 (step S12c), and a setting subprocess for setting a spacer jig 24 (step S12d) are performed in order in accordance with the flow chart of FIG. 12.

Next, a setting subprocess for setting a weight is performed (step S12e). As illustrated in FIG. 27, a weight 25 in which a guide hole 25b opposite an area including the two lead frames 5 is formed is located on the spacer jig 24. The weight 25 also includes a body portion 25a and the guide hole 25b. The body portion 25a has the shape of a cube. The body portion 25a is made of, for example, stainless steel. The weight 25 need only have a determined weight. Furthermore, the weight 25 need only be higher than the lead frames 5 protruding from the front surface of the spacer jig 24. The guide hole 25b is formed in the body portion 25a so that when the weight 25 is located on the spacer jig 24, the guide hole 25b will correspond to the area including the two lead frames 5 (bonding portions 5a). In this case, the guide hole 25b is rectangular in plan view. The weight 25 is supported on the spacer jig 24 and the lead frames 5 are situated in the guide hole 25b. As a result, the semiconductor unit 2 is pressed to the side of the radiation plate 6 by the weight 25 with the spacer jig 24 therebetween.

Next, a setting subprocess for setting a pressing jig is performed (step S12f). As illustrated in FIG. 28 and FIG. 29, a pressing jig 15 is inserted into the guide hole 25b of the weight 25 to set the pressing jig 15. The pressing jig 15 includes a pressing body portion 15a having a pressing surface 15a1 at the end and a locking portion 15b. This is the same with the first embodiment. However, the shape of the pressing body portion 15a (pressing surface 15a1) used in the second embodiment corresponds to that of the guide hole 25b. Furthermore, coating portions 15c corresponding to the bonding portions 5a of the lead frames 5 are formed in the pressing surface 15a1 of the pressing body portion 15a. The coating portions 15c are concave with respect to the pressing surface 15a1. The shape of the coating portions 15c corresponds in plan view to that of the bonding portions 5a and the depth of the coating portions 15c may be approximately equal to the thickness of the bonding portions 5a.

When the pressing jig 15 is inserted into the guide hole 25b to set the pressing jig 15, the bonding portions 5a of the lead frames 5 are coated with the coating portions 15c. At this time, the entire bonding portions 5a need only be covered with the coating portions 15c. Accordingly, it may be that the front surfaces of the bonding portions 5a will or will not be in contact with the bottoms of the coating portions 15c. The pressing surface 15a1 is in contact with the front surfaces of semiconductor chips 4. Furthermore, in this case, the locking portion 15b also suppresses the pressing jig 15 excessively pressing the bonding portions 5a and the semiconductor chips 4.

Next, a bonding subprocess is performed (step S12g). Heating is performed in a state in which the pressing jig 15 presses the bonding portions 5a of the lead frames 5 to the side of the insulated circuit board 3. As a result, a warp of each semiconductor chip 4 is corrected. This is the same with the first embodiment. Accordingly, the same effect that is obtained in the first embodiment is achieved. Furthermore, at this time, because the bonding portions 5a are covered with the coating portions 15c, scattering of bonding members 7c under the bonding portions 5a on the front surfaces of the semiconductor chips 4 is prevented.

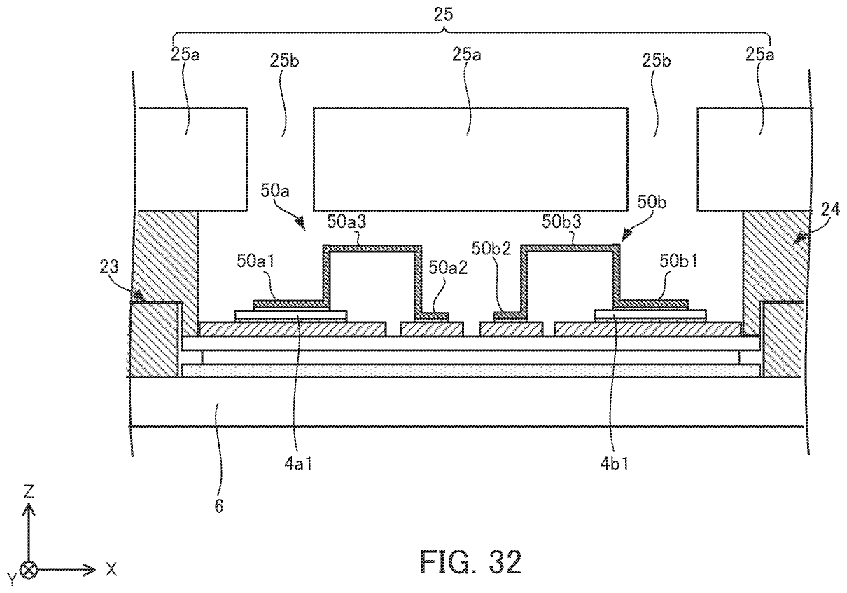

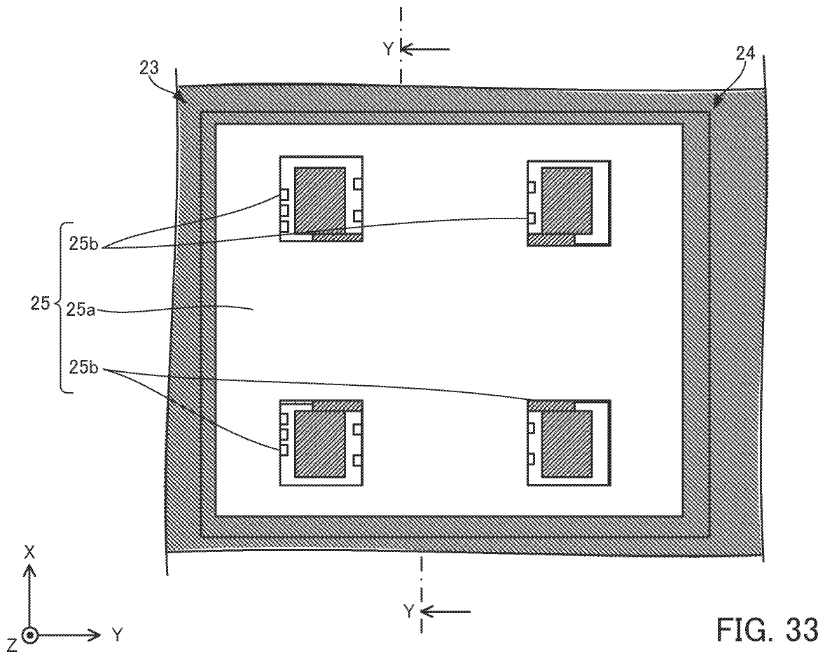

In the second embodiment, the description has been given with the guide hole 25b formed in the weight 25 opposite the area including the two lead frames 5 as an example. However, two guide holes 25b may be formed in the weight 25 according to lead frames 5 (see, for example, FIG. 32 and FIG. 33). In this case, a coating portion 15c is formed for each of pressing jigs 15 set in the guide holes 25b.

### Third Embodiment

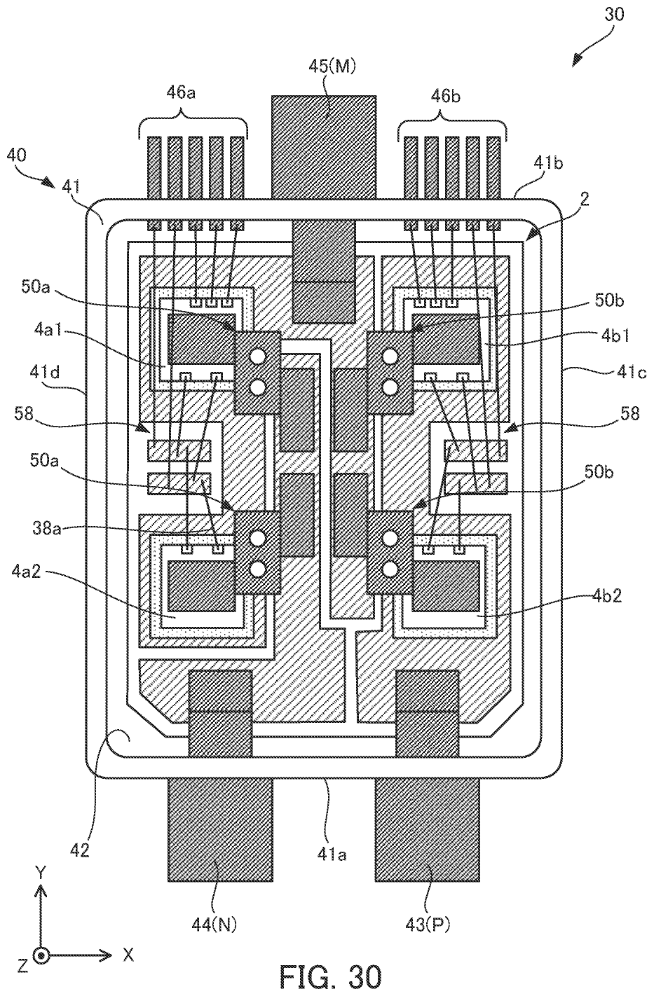

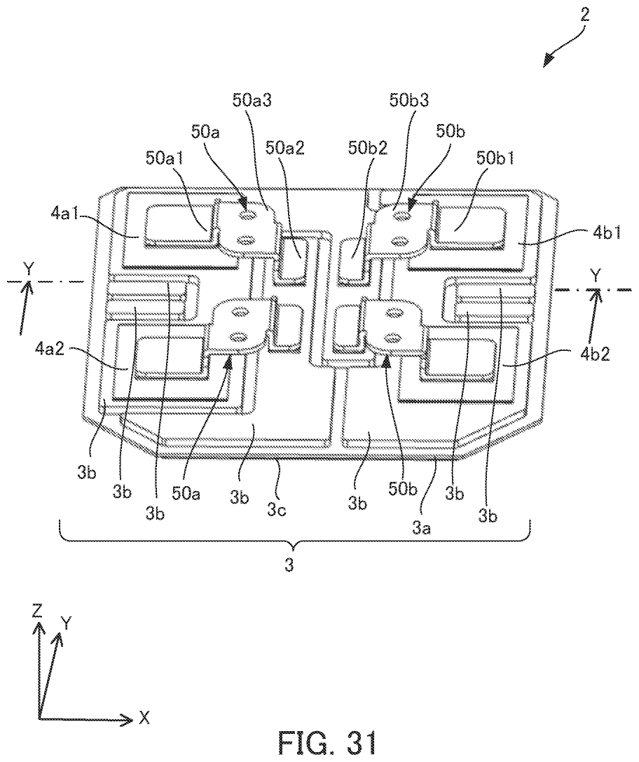

In a third embodiment, a method for manufacturing a semiconductor device different from that described in the first embodiment will be described with reference to FIG. 30 and FIG. 31. Components of a semiconductor device 30 which are the same as those included in the semiconductor device 1 according to the first embodiment are marked with the same numerals and descriptions of them may be omitted (or simplified). FIG. 30 is a plan view illustrative of the semiconductor device according to the third embodiment. FIG. 31 is a perspective view of a semiconductor unit included in the semiconductor device according to the third embodiment.

As illustrated in FIG. 30, the semiconductor device 30 includes a semiconductor unit 2 and a case 40 which houses the semiconductor unit 2. The inside of the case 40 may be sealed with a sealing member (not illustrated). Furthermore, the semiconductor device 30 includes a radiation plate 6 (see FIG. 32) which is located on the back surface of the case 40 and over which the semiconductor unit 2 is located. The details of the semiconductor unit 2 will be described later.

The case 40 is approximately rectangular in plan view and has a frame portion 41 including a pair of frame portion short sides 41a and 41b and a pair of frame portion long sides 41c and 41d. The case 40 has a housing portion 42 surrounded on all sides by the pair of frame portion short sides 41a and 41b and the pair of frame portion long sides 41c and 41d. The housing portion 42 is approximately rectangular in plan view. The semiconductor unit 2 is housed in the housing portion 42. If sealing is performed with a sealing member, then the inside of the housing portion 42 is sealed.

The sealing member used at this time may be a thermosetting resin such as epoxy resin, phenolic resin, maleimide resin, polyester resin, or the like. The sealing member is preferably epoxy resin. Furthermore, a filler may be added to the sealing member. Such a filler is a ceramic having an insulating property and high thermal conductivity and is silicon oxide, aluminum oxide, boron nitride, aluminum nitride, or the like. The filler content of the entire sealing member is higher than or equal to 10 vol % and lower than or equal to 70 vol %.

Furthermore, input terminals are located on the frame portion short side 41a of the case 40. Specifically, the input terminals are a P terminal 43 and an N terminal 44 located along the frame portion short side 41a. An output terminal is located on the frame portion short side 41b of the front surface of the case 40 on the opposite side of the frame portion short side 41a on which the input terminals are located. Specifically, the output terminal is an M terminal 45 located on the frame portion short side 41b.

The P terminal 43 and the N terminal 44 and the M terminal 45 are located with the housing portion 42 therebetween. Furthermore, with the case 40 control terminals 46a and 46b are located on both sides of the M terminal 45. The other end portions of these terminals are electrically connected to semiconductor chips of the semiconductor unit 2 housed in the housing portion 42. For example, the other end portions of the control terminals 46a and 46b are electrically connected via wires 58 to control electrodes, which are gate electrodes, of semiconductor chips 4a1 and 4b1, respectively. In addition, the other end portions of P terminal 43, the N terminal 44 and the M terminal 45 are electrically connected to main electrodes, such as emitter electrodes (or source electrodes) or collector electrodes (or drain electrodes), of semiconductor chips 4a2 and 4b2.

Furthermore, a cooling unit (not illustrated) may be fixed to the back surface of the case 40 to which the radiation plate 6 is fixed. For example, this cooling unit is made of metal, such as aluminum, iron, silver, copper, or an alloy containing at least one of them, having high thermal conductivity. In addition, the cooling unit is a heat sink including one or more fins, a water-cooling jacket, or the like. Moreover, the radiation plate 6 may be integrated with the cooling unit.

Furthermore, as illustrated in FIG. 31, the semiconductor unit 2 includes an insulated circuit board 3, the semiconductor chips 4a1, 4a2, 4b1, and 4b2, and lead frames 50a and 50b. The insulated circuit board 3 includes an insulating plate 3a, a plurality of circuit patterns 3b formed over the insulating plate 3a, and a metal plate 3c formed on the back surface of the insulating plate 3a. This is the same with the first embodiment. Each of the semiconductor chips 4a1 and 4b1 includes an RC-IGBT described in the first embodiment.

The lead frames 50a directly connect the semiconductor chips 4a1 and 4a2 and a circuit pattern 3b. Each lead frame 50a includes a bonding portion 50a1 bonded to a main electrode on the front surface of the semiconductor chip 4a1 or 4a2, a bonding portion 50a2 bonded to the circuit pattern 3b, and a wiring portion 50a3 which connects the bonding portions 50a1 and 50a2 (see, for example, FIG. 32). The lead frames 50b directly connect the semiconductor chips 4b1 and 4b2 and a circuit pattern 3b. Each lead frame 50b includes a bonding portion 50b1 bonded to a main electrode on the front surface of the semiconductor chip 4b1 or 4b2, a bonding portion 50b2 bonded to the circuit pattern 3b, and a wiring portion 50b3 which connects the bonding portions 50b1 and 50b2 (see, for example, FIG. 32).

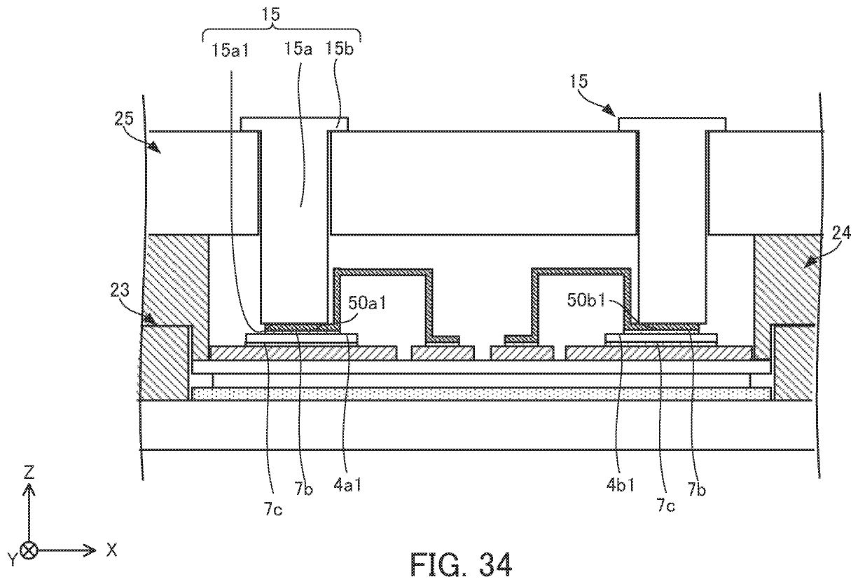

The semiconductor unit 2 in the third embodiment and the semiconductor device 30 including the semiconductor unit 2 are manufactured in accordance with the flow chart of FIG. 2 in the first embodiment. Furthermore, steps S11 and S12 included in this flow chart are performed and pressing jigs 15 are used in the same way as with the first or second embodiment. A case where the pressing jigs 15 are used in a bonding process of step S12 will now be described with reference to FIGS. 32 through 34. FIG. 32 is a sectional view illustrative of a weight setting subprocess included in the bonding process included in a method for manufacturing the semiconductor device according to the third embodiment. FIG. 33 is a plan view illustrative of the weight setting subprocess included in the bonding process included in the method for manufacturing the semiconductor device according to the third embodiment. FIG. 34 is a sectional view illustrative of a pressing jig setting subprocess included in the bonding process included in the method for manufacturing the semiconductor device according to the third embodiment. FIG. 32 is a sectional view taken along the dot-dash line Y-Y of FIG. 33.

In step S11, the semiconductor unit 2 illustrated in FIG. 31 is manufactured. In step S12, a setting subprocess for setting the radiation plate 6 on a base jig 21 (step S12a), a fixing subprocess for fixing the radiation plate 6 (step S12b), a subprocess for positioning the semiconductor unit 2 (step S12c), and a subprocess for setting a spacer jig 24 (step S12d) are performed in accordance with the flow chart of FIG. 12. In the third embodiment, the height of the spacer jig 24 is greater than the height of the lead frames 50a and 50b of the semiconductor unit 2 from the front surface of the insulated circuit board 3.

Next, a setting subprocess for setting a weight is performed (step S12e). As illustrated in FIG. 32 and FIG. 33, a weight 25 in which four guide holes 25b opposite the bonding portions 50a1 and 50a2 of the lead frame 50a and the bonding portions 50b1 and 50b2 of the lead frame 50b are formed is located on the spacer jig 24 (FIG. 32 illustrates guide holes 25b of the weight 25 opposite the bonding portions 50a1 and 50b1). The weight 25 also include a body portion 25a and the four guide holes 25b. The body portion 25a has the shape of a cube. The body portion 25a is made of, for example, stainless steel. The weight 25 need only have a determined weight. The guide holes 25b are formed in the body portion 25a so that when the weight 25 is located on the spacer jig 24, the guide holes 25b will correspond to the bonding portions 50a1 and 50a2 of the lead frame 50a and the bonding portions 50b1 and 50b2 of the lead frame 50b. In FIG. 32 and FIG. 33, the guide holes 25b are rectangular in plan view. The weight 25 is supported on the spacer jig 24 and the bonding portions 50a1 and 50a2 of the lead frame 50a and the bonding portions 50b1 and 50b2 of the lead frame 50b are situated under the guide holes 25b. As a result, the semiconductor unit 2 is pressed to the side of the radiation plate 6 by the weight 25 with the spacer jig 24 therebetween.

Next, a setting subprocess for setting a pressing jig is performed (step S12f). As illustrated in FIG. 34, the pressing jigs 15 are inserted into the guide holes 25b of the weight 25 to set the pressing jigs 15. Each pressing jig 15 includes a pressing body portion 15a having a pressing surface 15a1 at the end and a locking portion 15b. This is the same with the first embodiment. However, the shape of the pressing body portions 15a (pressing surfaces 15a1) used in this case corresponds to that of the guide holes 25b.

When the pressing jigs 15 are inserted into the four guide holes 25b to set the pressing jigs 15, the pressing surfaces 15a1 are in contact with the bonding portions 50a1, 50a2, 50b1, and 50b2. FIG. 34 illustrates the bonding portions 50a1 and 50b1 with which the pressing surfaces 15a1 of the pressing jigs 15 are in contact. Furthermore, in this case, the locking portions 15b also suppress the pressing jigs 15 excessively pressing the bonding portions 50a1, 50a2, 50b1, and 50b2 and the semiconductor chips 4.

Next, a bonding subprocess is performed (step S12g). Heating is performed in a state in which the pressing jigs 15 press the bonding portions 50a1 and 50a2 of the lead frame 50a and the bonding portions 50b1 and 50b2 of the lead frame 50b to the side of the insulated circuit board 3. A warp of each of the semiconductor chips 4a1, 4a2, 4b1, and 4b2 is corrected. This is the same with the first embodiment. As a result, the same effect that is obtained in the first embodiment is achieved.

Coating portions 15c may be formed, as with the second embodiment, in the pressing surfaces 15a1 of the pressing jigs 15 in the third embodiment. In this case, the bonding portions 50a1 and 50a2 of the lead frame 50a and the bonding portions 50b1 and 50b2 of the lead frame 50b are also covered with the coating portions 15c. This prevents scattering of bonding members used for bonding the bonding portions 50a1, 50a2, 50b1, and 50b2 on the front surfaces of the semiconductor chips 4a1, 4a2, 4b1, and 4b2, respectively.

By adopting the above semiconductor device manufacturing method and jig set, a semiconductor device in which the occurrence of an electrical failure is suppressed and which prevents deterioration in reliability is manufactured.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device manufacturing method, comprising:
a preparing process for preparing a conductive plate, a semiconductor chip arranged over the conductive plate with a first bonding material therebetween, and a connection terminal including a bonding portion arranged over the semiconductor chip with a second bonding material therebetween;
a first jig arrangement process for arranging a first guide jig, through which a first guide hole pierces, over the conductive plate, such that the first guide hole corresponds to the bonding portion in a plan view of the semiconductor device; and
a first pressing process for inserting a pillar-shaped pressing jig, which includes a pressing portion at a lower end portion thereof, into the first guide hole, and pressing the bonding portion of the connection terminal to a side of the conductive plate with the pressing portion.

2. The semiconductor device manufacturing method according to claim 1, wherein the first pressing process further includes performing heating while pressing the bonding portion of the connection terminal with the pressing portion of the pressing jig.

3. The semiconductor device manufacturing method according to claim 1, wherein the pressing jig further includes, at an upper end portion thereof, a locking portion lockable by the first guide jig.

4. The semiconductor device manufacturing method according to claim 1, wherein
the preparing process further includes providing an insulated circuit board that has:
an insulating plate,
the conductive plate, which is formed on a front surface of the insulating plate, and
a metal plate formed on a back surface of the insulating plate.

5. The semiconductor device manufacturing method according to claim 4, wherein
the preparing process further includes preparing a radiation plate and the insulated circuit board, and
the semiconductor device manufacturing method further includes, after the first pressing process, a second pressing process for arranging the insulated circuit board, to which the semiconductor chip and the bonding portion of the connection terminal are bonded in order, over the radiation plate with a third bonding material therebetween, and pressing the bonding portion of the connection terminal with the pressing jig.

6. The semiconductor device manufacturing method according to claim 5, wherein the second pressing process further includes performing heating while pressing the bonding portion of the connection terminal with the pressing portion of the pressing jig.

7. The semiconductor device manufacturing method according to claim 5, wherein the second pressing process further includes
arranging a spacer jig having an opening portion, such that the opening portion corresponds to the semiconductor chip, and the semiconductor chip and the bonding portion of the connection terminal are in the opening portion in the plan view, and
arranging the first guide jig on the spacer jig.

8. The semiconductor device manufacturing method according to claim 7, wherein a height of the opening portion of the spacer jig is greater than a sum of a height of the semiconductor chip and a height of the bonding portion of the connection terminal arranged over the semiconductor chip.

9. The semiconductor device manufacturing method according to claim 7, wherein arranging the spacer jig includes forming a guide portion extending toward the bonding portion on an inside of the opening portion of the spacer jig.

10. The semiconductor device manufacturing method according to claim 1, wherein the first pressing process further includes forming a semiconductor unit by bonding the semiconductor chip to the conductive plate with the first bonding material, and by bonding the bonding portion of the connection terminal to the semiconductor chip with the second bonding material.

11. The semiconductor device manufacturing method according to claim 1, wherein:
the pressing portion of the pressing jig has a flat surface, with a concave housing portion formed in the flat surface for the bonding portion of the connection terminal to be housed therein.

12. A jig set for manufacturing a semiconductor device having
a conductive plate,
a semiconductor chip arranged over the conductive plate with a first bonding material therebetween, and
a connection terminal including a bonding portion arranged over the semiconductor chip with a second bonding material therebetween,
the jig set comprising:
a first guide jig to be arranged over the conductive plate, the first guide jig having a first guide hole piercing therethrough corresponding to the bonding portion of the connection terminal in a plan view of the jig set; and
a pressing jig which has a shape of a pillar, which has a pressing portion at a lower end portion thereof for insertion into the first guide hole, and which is configured to press the bonding portion of the connection terminal to a side of the conductive plate with the pressing portion.

13. The jig set according to claim 12, wherein the pressing jig further includes a locking portion at an upper end portion thereof, by which the pressing jig, when inserted into the first guide hole, is lockable by the first guide jig.
